(19) United States
(12) Patent Application Publication
(10) Pub. No.: US 2025/0299977 A1
(43) Pub. Date: Sep. 25, 2025

(54) SUBSTRATE PROCESSING APPARATUS

(71) Applicant: SCREEN Holdings Co., Ltd., Kyoto (JP)

(72) Inventors: Michinori IWAO, Kyoto-shi (JP); Yukifumi YOSHIDA, Kyoto-shi (JP); Tomohiro UEMURA, Kyoto-shi (JP); Shoyo MINAMI, Kyoto-shi (JP); Yusuke UEDA, Kyoto-shi (JP)

(21) Appl. No.: 19/075,786

(22) Filed: Mar. 11, 2025

(30) Foreign Application Priority Data
Mar. 21, 2024 (JP) 2024-044770

(51) Int. Cl. H01L 21/67; H01L 21/677

(52) U.S. Cl. CPC H01L 21/67034; H01L 21/67057; H01L 21/67757

(57) ABSTRACT

A substrate processing apparatus includes a treatment tank, a substrate holder, a discharge part, and an organic solvent recovery part. The treatment tank stores liquid. The substrate holder holds a plurality of substrates and immerses the plurality of substrates in a liquid in the treatment tank. The discharge part discharges a second concentration liquid having a solvent concentration higher than that of the first concentration liquid while avoiding at least a part of the first concentration liquid in the liquid from the treatment tank. The organic solvent recovery part includes a dewaterer that separates water from the second concentration liquid discharged by the discharge part to generate a third concentration liquid having a solvent concentration higher than that of the second concentration liquid.

### BACKGROUND

### Technical Field

The present disclosure relates to a substrate processing apparatus.

### Description of the Background Art

Japanese Patent Application Laid-Open No. 2017-41505 discloses an IPA recovery system that recovers water-containing IPA (isopropyl alcohol) discharged from a processing unit that processes a substrate. The IPA recovery system includes a storage tank, a circulation pipe, a pump, a dewatering unit, and a filter. The storage tank is supplied with water-containing IPA from the processing unit. The circulation pipe is connected to the storage tank, and returns the water-containing IPA from the storage tank to the storage tank. The pump is provided in the circulation pipe, and feeds the water-containing IPA from the upstream end toward the downstream end of the circulation pipe. The filter is provided in the circulation pipe to remove foreign substances in the water-containing IPA. The dewatering unit is provided in the circulation pipe and removes moisture from the water-containing IPA.

The recovery system circulates the water-containing IPA through a circulation path including a storage tank and a circulation pipe. This circulation causes water-containing IPA to pass through the filter and dewatering unit. As a result, the IPA concentration of water-containing IPA during circulation increases, and foreign substances in water-containing IPA are reduced. That is, by this circulation, water-containing IPA having a high IPA concentration and being clean is stored in the storage tank. The water-containing IPA in this storage tank is again supplied to the processing unit. As a result, the amount of discarded IPA can be reduced.

When the mixed liquid having a low solvent concentration is recovered from the processing unit to the storage tank, there is a problem that the time required to increase the solvent concentration of the mixed liquid in the storage tank becomes long.

### SUMMARY

According to one aspect, a substrate processing apparatus includes: a treatment tank that stores a liquid; a substrate holder that holds a plurality of substrates and immerses the plurality of substrates in the liquid in the treatment tank; a discharge part that discharges a second concentration liquid having a solvent concentration higher than that of a first concentration liquid, avoiding at least a part of the first concentration liquid in the liquid, from the treatment tank that stores the liquid containing water and an organic solvent having a specific gravity smaller than that of the water in a concentration distribution in which a solvent concentration is higher on an upper side than a lower side; and an organic solvent recovery part including a dewaterer that separates water from the second concentration liquid discharged by a discharge part to generate a third concentration liquid having a solvent concentration higher than that of the second concentration liquid.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a view schematically illustrating an example of a substrate processing apparatus according to a first embodiment;

FIG. 2 is a view schematically illustrating another example of a second concentration discharge part;

FIG. 3 is a flowchart illustrating an example of processing of a substrate by a processing unit according to the first embodiment;

FIGS. 4 and 5 are diagrams each illustrating an example of a temporal change of a state of a processing unit;

FIG. 6 is a view schematically showing an example of an organic solvent recovery part;

FIG. 7 is a diagram schematically illustrating an example of a substrate processing apparatus according to a first example of a second embodiment;

FIG. 8 is a flowchart illustrating an example of an operation of a processing unit according to the first example of the second embodiment;

FIG. 9 is a diagram illustrating an example of a temporal change of a state of the processing unit;

FIG. 10 is a diagram illustrating an example of a temporal change of a state of the processing unit that discharges liquid from a treatment tank;

FIG. 11 is a view schematically illustrating an example of a substrate processing apparatus according to a second example of the second embodiment;

FIG. 12 is a flowchart illustrating an operation example of the substrate processing apparatus according to the second example;

FIGS. 13 and 14 are diagrams each illustrating an example of a temporal change of a state of a processing unit according to the second example;

FIG. 15 is a view schematically illustrating a third example of the substrate processing apparatus according to the second embodiment;

FIG. 16 is a view showing an example of a temporal change of a state of a processing unit after a solvent substitution step;

FIG. 17 is a view schematically illustrating an example of a substrate processing apparatus according to a third embodiment; and

FIG. 18 is a diagram schematically showing an example of a temporal change of a state of a processing unit in a second concentration discharging step according to the third embodiment.

### DESCRIPTION OF THE PREFERRED EMBODIMENTS

Hereinafter, embodiments will be described in detail with reference to the drawings. In the drawings, dimensions and the number of parts are exaggerated or simplified as necessary for easy understanding. Portions having similar configurations and functions are denoted by the same reference numerals, and redundant description will be omitted in the following description.

Furthermore, in the following description, similar constituent elements are denoted by the same reference numerals, and names and functions thereof are also similar. Therefore, detailed description thereof may be omitted in order to avoid duplication.

In addition, in the following description, even if ordinal numbers such as “first” or “second” are used, these terms are used for convenience to facilitate understanding of the contents of the embodiments, and are not limited to the order that can occur by these ordinal numbers.

Where expressions indicating a relative or absolute positional relationship (e.g., “in one direction”, “along one direction”, “parallel”, “orthogonal”, “center”, “concentric”, “coaxial”, etc.) are used, the expressions shall not only strictly represent the positional relationship, but also represent a state of being displaced relative to an angle or distance to the extent that a tolerance or comparable function is obtained, unless otherwise specified. When an expression indicating an equal state (for example, “same”, “equal”, “homogeneous”, or the like) is used, unless otherwise specified, the expression not only represents a quantitatively strictly equal state, but also represents a state in which there is a difference in obtaining a tolerance or a similar function. In a case where an expression indicating a shape (for example, “quadrangular” or “cylindrical”) is used, unless otherwise specified, the expression not only represents the shape geometrically and strictly, but also represents a shape having, for example, unevenness or chamfering within a range in which the same level of effect can be obtained. When the expression “comprising”, “comprising”, “comprising”, “including” or “having” one component is used, the expression is not an exclusive expression excluding the presence of other components. When the expression “at least any one of A, B, and C” is used, the expression includes only A, only B, only C, any two of A, B and C, and all of A, B and C.

### First Embodiment

### Outline of Substrate Processing Apparatus

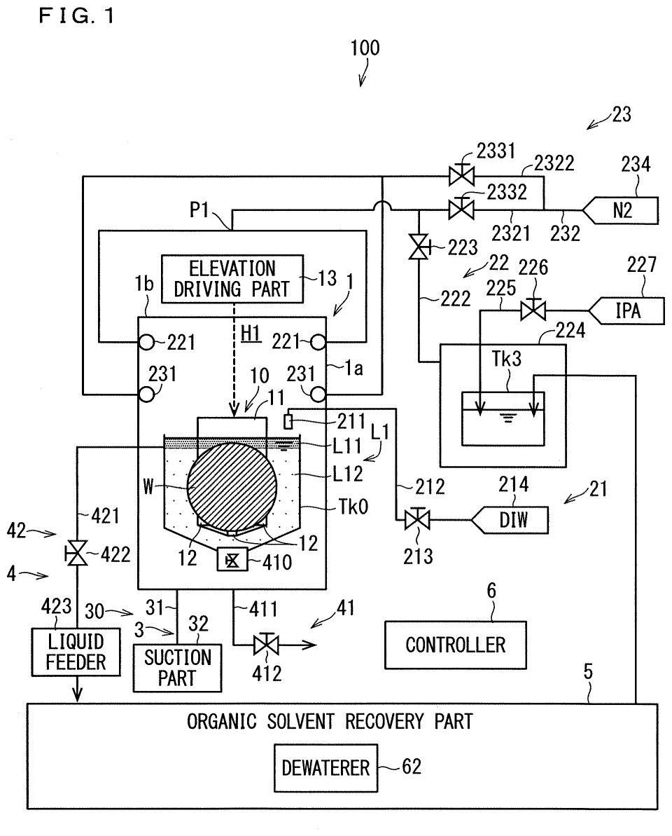

FIG. 1 is a diagram schematically illustrating an example of a substrate processing apparatus 100 according to a first embodiment. In the example of FIG. 1, the substrate processing apparatus 100 is a so-called batch type processing apparatus that collectively processes a plurality of substrates W to be processed. The substrate W to be processed by the substrate processing apparatus 100 is, for example, a semiconductor substrate. The shape of the substrate W to be processed is, for example, a disk shape.

As shown in FIG. 1, the substrate processing apparatus 100 includes a processing unit 1, a discharge part 4, an organic solvent recovery part 5, and a controller 6.

The processing unit 1 performs treatment using pure water and an organic solvent on the plurality of substrates W. As illustrated in FIG. 1, the processing unit 1 includes a treatment tank Tk0 and a substrate holder 10. A liquid L1 is stored in the treatment tank Tk0. Here, the liquid L1 is a liquid containing water and an organic solvent. The specific gravity of the organic solvent is smaller than the specific gravity of water. Therefore, the liquid L1 stored in the treatment tank Tk0 has a concentration distribution in which the solvent concentration is higher on the upper side than on the lower side. The solvent concentration referred to herein is the concentration of the organic solvent in the liquid L1.

In the example of FIG. 1, a high concentration portion L11 is formed in the upper portion of the liquid L1 stored in the treatment tank Tk0. The high concentration portion L11 is a portion having a relatively high solvent concentration in the liquid L1. Hereinafter, a portion of the liquid L1 below the high concentration portion L11 is also referred to as a low concentration portion L12. The low concentration portion L12 is a portion having a relatively low solvent concentration in the liquid L1. The high concentration portion L11 may have a concentration distribution in which the solvent concentration tends to increase on the upper side. The low concentration portion L12 may be substantially water. That is, the solvent concentration of the low concentration portion L12 may be substantially 0 and uniform. Alternatively, the low concentration portion L12 may have a concentration distribution in which the solvent concentration tends to increase on the upper side.

Such a concentration distribution can be formed, as an example, in the liquid L1 in the treatment tank Tk0 by a series of processing described later on the substrate W. Alternatively, also when the liquid L1 in the treatment tank Tk0 in which water and the organic solvent are mixed at a more uniform concentration is left for a long time, the concentration distribution can be formed in the liquid L1. This is because since the specific gravity of the organic solvent is smaller than the specific gravity of water, the organic solvent in the treatment tank Tk0 increases in the liquid L1 with the lapse of time.

The substrate holder 10 holds the plurality of substrates W in a standing posture. The standing posture here is a posture in which the thickness direction of the substrate W is along the horizontal direction (direction perpendicular to the paper surface of FIG. 1). In addition, the substrate holder 10 holds the plurality of substrates W in a state where the plurality of substrates W are arranged along the thickness direction (direction perpendicular to the paper surface of FIG. 1). The substrate holder 10 can hold the plurality of substrates W in a state of being immersed in the liquid L1 in the treatment tank Tk0.

The discharge part 4 discharges the liquid L1 from the treatment tank Tk0. The discharge part 4 includes a first concentration discharge part 41 and a second concentration discharge part 42. The first concentration discharge part 41 will be described later.

The second concentration discharge part 42 discharges the second concentration liquid having a solvent concentration higher than that of the first concentration liquid from the treatment tank Tk0 while avoiding at least a part of the first concentration liquid in the liquid L1. The at least part of the first concentration liquid is a liquid having a low solvent concentration in the liquid L1, and is a lower portion in the liquid L1. That is, the first concentration liquid is a liquid mainly belonging to the low concentration portion L12. On the other hand, the second concentration liquid is a liquid mainly belonging to the high concentration portion L11. The solvent concentration of the second concentration liquid may be, for example, 50 wt % or more, 60 wt % or more, or 70 wt % or more.

In the example of FIG. 1, the second concentration discharge part 42 includes a second discharge pipe 421. In the example of FIG. 1, the upstream end portion (upstream port) of the second discharge pipe 421 is provided at a height position corresponding to the second concentration liquid, and is immersed in the liquid L1 in the treatment tank Tk0. The height position of the upstream end portion of the second discharge pipe 421 may be, for example, on the upper end side of the central portion in the vertical direction of the treatment tank Tk0. In the example of FIG. 1, the upstream end portion of the second discharge pipe 421 is located near the boundary between the high concentration portion L11 and the low concentration portion L12.

A portion of the liquid L1 in the treatment tank Tk0 below the upstream end portion of the second discharge pipe 421 is less likely to flow into the second discharge pipe 421. Since the solvent concentration in the lower portion is low, the liquid L1 having a relatively low solvent concentration is less likely to flow into the second discharge pipe 421. On the other hand, a portion of the liquid L1 in the treatment tank Tk0, which is the same as or above the upstream end portion, is likely to flow into the second discharge pipe 421. Since the solvent concentration in the upper portion is high, the liquid L1 having a relatively high solvent concentration flows into the second discharge pipe 421 as the second concentration liquid. In the example of FIG. 1, the upstream end portion of the second discharge pipe 421 is connected to the side wall of the treatment tank Tk0. The downstream end portion of the second discharge pipe 421 is connected to the organic solvent recovery part 5.

As illustrated in FIG. 1, a discharge valve 422 is interposed in the second discharge pipe 421. When the controller 6 opens the discharge valve 422, the upper portion (that is, the second concentration liquid) of the liquid L1 is discharged through the second discharge pipe 421, and the second concentration liquid is supplied to the organic solvent recovery part 5 through the second discharge pipe 421. As illustrated in FIG. 1, a liquid feeder 423 may be provided in the second discharge pipe 421. The liquid feeder 423 is, for example, an ejector, and feeds the second concentration liquid from the treatment tank Tk0 toward the organic solvent recovery part 5.

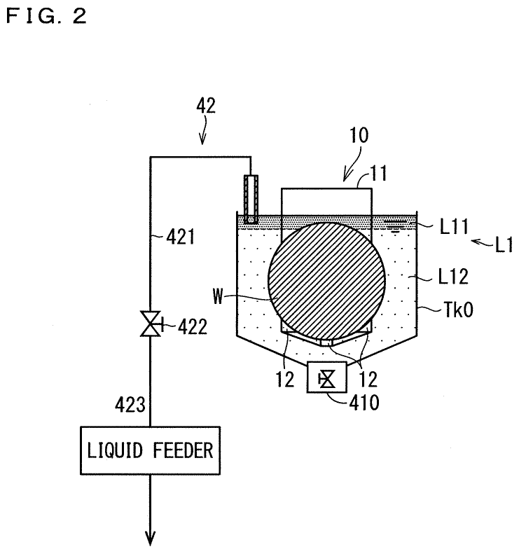

FIG. 2 is a diagram schematically illustrating another example of the second concentration discharge part 42. Also in the example of FIG. 2, the upstream end portion of the second discharge pipe 421 is provided at a height position corresponding to the second concentration liquid. However, the second discharge pipe 421 extends upward from the upstream end portion and penetrates the liquid surface of the liquid L1. The second discharge pipe 421 is bent and extends downward outside the treatment tank Tk0. In such a second concentration discharge part 42, the liquid feeder 423 is operated in a state where the controller 6 opens the discharge valve 422, whereby the liquid L1 can be sucked into the upstream end portion of the second discharge pipe 421. By this suction, a portion of the liquid L1 above the upstream end portion of the second discharge pipe 421 mainly flows into the second discharge pipe 421. Therefore, the second concentration liquid having a relatively high solvent concentration flows into the second discharge pipe 421. The second concentration liquid is supplied to the organic solvent recovery part 5 through the second discharge pipe 421.

The organic solvent recovery part 5 includes a dewaterer 62. The dewaterer 62 separates water from the second concentration liquid discharged by the discharge part 4 to generate a third concentration liquid having a solvent concentration higher than that of the second concentration liquid. An example of a specific configuration of the organic solvent recovery part 5 will be described in detail later.

The controller 6 controls various configurations of the substrate processing apparatus 100. The controller 6 includes, for example, a general computer having an electric circuit. As an example, the controller 6 includes a central processor unit (CPU) as a central processing unit that performs various types of arithmetic processing (data processing), a read only memory (ROM) that stores a basic program and the like, a random access memory (RAM) that is used as a work area when the CPU performs predetermined processing (data processing), a storage apparatus configured by a nonvolatile storage apparatus such as a flash memory or a hard disk apparatus, a bus line that connects these, and the like. A program that defines processing executed by the controller 6 may be stored in the storage apparatus, the RAM, or the like. In this case, for example, when the CPU executes the program, each part of the substrate processing apparatus 100 may be controlled by the controller 6, and processing defined by the program may be executed in the substrate processing apparatus 100. That is, a circuit that performs processing defined by the program may be implemented in the controller 6 by the CPU executing the program. However, a part or all of the control performed by the controller 6 (a part or all of the circuit implemented by the controller 6) may be executed (implemented) by hardware such as a dedicated logic circuit.

In such a substrate processing apparatus 100, as described above, the discharge part 4 supplies the second concentration liquid having a relatively high solvent concentration to the organic solvent recovery part 5. Therefore, the organic solvent recovery part 5 can generate the third concentration liquid from the second concentration liquid in a shorter time and with smaller energy as compared with the case of generating the third concentration liquid from the first concentration liquid.

Hereinafter, a specific configuration and an example of a specific operation of the processing unit 1 will be described in detail. Thereafter, an example of a specific configuration and a specific operation of the organic solvent recovery part 5 will be described in detail.

### Detailed Example of Processing Unit

In the example of FIG. 1, the substrate holder 10 includes a plate portion 11, a plurality of holding rods 12, and an elevation driving part 13. The plate portion 11 has a plate shape, and is provided in a posture in which a thickness direction thereof is along a thickness direction of the substrate W (a direction perpendicular to the paper surface in FIG. 1). Each of the holding rods 12 extends along the thickness direction of the substrate W, and a base end portion thereof is connected to the plate portion 11. The plurality of holding rods 12 are located below the plurality of substrates W, and are provided at intervals along the circumferential direction of the substrates W. A plurality of holding grooves (not illustrated) are formed in each of the holding rods 12 at intervals in the thickness direction of the substrate W, and a part of the substrate W is inserted into each of the holding grooves. By this insertion into the holding grooves, the substrate holder 10 holds the plurality of substrates W in a standing posture.

The elevation driving part 13 integrally moves up and down the plate portion 11, the plurality of holding rods 12, and the plurality of substrates W. The elevation driving part 13 includes, for example, a driving source such as a motor and a power transmission part that transmits power from the driving source to the plate portion 11. The power transmission part is, for example, a transmission part such as a ball screw mechanism and a cam mechanism.

In the example of FIG. 1, the processing unit 1 includes a chamber 1a forming a treatment chamber H1. The internal space of the chamber 1a corresponds to the treatment chamber H1. The chamber 1a includes a lid 1b that can be opened and closed at a ceiling portion thereof. The chamber 1a is provided with an opening/closing drive part (for example, a motor) (not illustrated) that opens and closes the lid 1b. In a state where the lid 1b is opened, the substrate holder 10 moves up and down the plurality of substrates W between the position inside the treatment chamber H1 and the position above the treatment chamber H1. In the example of FIG. 1, a substrate W located inside the treatment chamber H1 is illustrated. As described later, the substrate holder 10 carries the plurality of untreated substrates W into the treatment chamber H1, and discharges the plurality of substrates W treated in the treatment chamber H1 from the treatment chamber H1.

The treatment chamber H1 accommodates a treatment tank Tk0. The substrate holder 10 can also move up and down the plurality of substrates W between an immersion position and a drying position to be described next inside the treatment chamber H1. The immersion position is a position where the plurality of substrates W are immersed in the liquid in the treatment tank Tk0. In the example of FIG. 1, the substrate W located at the immersion position is shown. The drying position is a position where the plurality of substrates W are located above the treatment tank Tk0. As described later, the processing unit 1 performs pure water treatment on the substrate W stopped at the immersion position, and performs drying treatment on the substrate W stopped at the drying position.

In the example of FIG. 1, the processing unit 1 further includes a pure water supply part 21, a solvent vapor supply part 22, and an inert gas supply part 23. The pure water supply part 21 supplies pure water (that is, deionized water) into the treatment tank Tk0 to store the pure water in the treatment tank Tk0. In the example of FIG. 1, the pure water supply part 21 includes a nozzle 211, a supply pipe 212, and a supply valve 213. The nozzle 211 ejects pure water toward the treatment tank Tk0. In the example of FIG. 1, the nozzle 211 is provided above the treatment tank Tk0 in the treatment chamber H1. The nozzle 211 is connected to the downstream end portion of the supply pipe 212, and the upstream end portion of the supply pipe 212 is connected to a pure water supply source 214. The supply pipe 212 is a pipe through which pure water flows toward the treatment tank Tk0. The supply valve 213 is inserted into the supply pipe 212.

When the controller 6 opens the supply valve 213, pure water is ejected from the nozzle 211 toward the treatment tank Tk0. As a result, pure water is stored in the treatment tank Tk0. When a sufficient amount of pure water is stored in the treatment tank Tk0, the controller 6 closes the supply valve 213.

The solvent vapor supply part 22 supplies vapor of an organic solvent to a space above the treatment tank Tk0 in the treatment chamber H1. As described later, the solvent vapor supply part 22 supplies vapor of the organic solvent into the treatment chamber H1 in an immersion state in which the plurality of substrates W are immersed in pure water in the treatment tank Tk0. A part of the vapor of the organic solvent reaches the liquid surface in the treatment tank Tk0 and is condensed on the liquid surface to form a liquid membrane of the organic solvent. Therefore, the liquid L1 is stored in the treatment tank Tk0 with the above-described concentration distribution. In other words, the above-described concentration distribution is formed in the liquid L1 in the treatment tank Tk0. Mainly, the liquid membrane of the organic solvent corresponds to the high concentration portion L11, and pure water below the liquid membrane of the organic solvent corresponds to the low concentration portion L12.

In the example of FIG. 1, solvent vapor supply part 22 includes an ejection pipe 221, a supply pipe 222, a supply valve 223, and a solvent vapor generator 224. The ejection pipe 221 is provided in the treatment chamber H1, and is provided at a position above the treatment tank Tk0 in the example of FIG. 1. The ejection pipe 221 has an ejection port, and ejects the vapor of the organic solvent from the ejection port. In the example of FIG. 1, two ejection pipes 221 are provided. The two ejection pipes 221 are arranged in the horizontal direction, and are provided on opposite sides of the plurality of substrates W in the horizontal direction. As an example, one of the ejection pipes 221 ejects vapor of an organic solvent toward the other.

The supply pipe 222 connects the ejection pipe 221 and the solvent vapor generator 224. The supply pipe 212 is a pipe through which vapor of an organic solvent flows toward the treatment chamber H1. In the example of FIG. 1, the supply pipe 222 branches into two, and each downstream end portion thereof is connected to the ejection pipe 221. The upstream end portion of the supply pipe 222 is connected to the solvent vapor generator 224.

The solvent vapor generator 224 generates vapor of an organic solvent, and causes the vapor to flow into the supply pipe 222. As shown in FIG. 1, the solvent vapor generator 224 includes a supply tank Tk3. Liquid containing an organic solvent is stored in the supply tank Tk3. The solvent vapor generator 224 includes a heater (not illustrated) that heats the organic solvent. The heater of the solvent vapor generator 224 heats the organic solvent to generate vapor of the organic solvent, and causes the vapor to flow into the supply pipe 222. The solvent vapor generator 224 may cause a carrier gas to flow into the supply pipe 222 together with the vapor of the organic solvent. As the carrier gas, an inert gas can be applied. The inert gas is, for example, a rare gas or a nitrogen gas. The rare gas is, for example, argon gas or neon gas.

The controller 6 opens the supply valve 223 to cause the solvent vapor generator 224 to generate vapor of the organic solvent. As a result, the vapor of the organic solvent is ejected from the ejection pipe 221. A part of the vapor of the organic solvent ejected from the ejection pipe 221 into the treatment chamber H1 reaches the liquid surface of the pure water stored in the treatment tank Tk0. This vapor is cooled by pure water and condensed to form a liquid membrane of an organic solvent on the liquid surface of the pure water.

In the example of FIG. 1, the supply tank Tk3 is connected to a new liquid supply source 227 through a new liquid pipe 225. That is, the downstream end portion of the new liquid pipe 225 is connected to the supply tank Tk3, and the upstream end portion of the new liquid pipe 225 is connected to the new liquid supply source 227. The new liquid supply source 227 is a supply source of an unused organic solvent (for example, IPA having a concentration of 99.8 wt % or more) that has never been supplied to the substrate W. A new liquid valve 226 is interposed in the new liquid pipe 225.

The inert gas supply part 23 supplies an inert gas into the treatment chamber H1. In the example of FIG. 1, the inert gas supply part 23 includes an ejection pipe 231, a supply pipe 232, a supply valve 2331, and a supply valve 2332. In the example of FIG. 1, the ejection pipe 221 is also used for the inert gas supply part 23. That is, the ejection pipe 221 can also eject an inert gas. The ejection pipe 231 is provided in the treatment chamber H1, and in the example of FIG. 1, the ejection pipe 231 is provided at a position below the ejection pipe 221 and above the treatment tank Tk0. The ejection pipe 231 has an ejection port, and ejects the inert gas from the ejection port into the treatment chamber H1. In the example of FIG. 1, two ejection pipes 231 are provided. The two ejection pipes 231 are arranged in the horizontal direction, and are provided on opposite sides of the plurality of substrates W in the horizontal direction. As an example, one of the ejection pipes 231 ejects an inert gas toward the other. As described later, the inert gas can be used for drying the plurality of substrates W and adjusting the pressure in the treatment chamber H1.

The supply pipe 232 connects each of the ejection pipe 221 and the ejection pipe 231 to the inert gas supply source 234. The supply pipe 232 is a pipe through which an inert gas flows toward the treatment chamber H1. The upstream end portion of the supply pipe 232 is connected to the inert gas supply source 234. The supply pipe 232 branches into two branch pipes 2321 and 2322. The downstream end portion of the branch pipe 2321 is connected to a portion of the supply pipe 222 between the supply valve 223 and the branch point P1. The branch pipe 2322 further branches into two, and each downstream end portion thereof is connected to the ejection pipe 231. The supply valve 2331 is interposed in the branch pipe 2321, and the supply valve 2332 is interposed in the branch pipe 2322.

When the controller 6 opens the supply valve 2331, the inert gas is ejected from the ejection pipe 221. When the controller 6 opens the supply valve 2332, the inert gas is ejected from the ejection pipe 231.

In the example of FIG. 1, the processing unit 1 also includes a gas discharge part 3. The gas discharge part 3 sucks the gas in the treatment chamber H1. The gas discharge part 3 can reduce the pressure in the treatment chamber H1 by sucking the gas. The gas discharge part 3 includes a discharge pipe 31 and a suction part 32. The suction part 32 is connected to the chamber 1a through the discharge pipe 31. The suction part 32 is, for example, a pump (a water sealed vacuum pump as a specific example). In the example of FIG. 1, the upstream end portion of the discharge pipe 31 is connected to the bottom of the chamber 1a.

When the controller 6 operates the suction part 32, the gas in the treatment chamber H1 is discharged through the discharge pipe 31. As a result, the pressure in the treatment chamber H1 can be reduced.

When the gas discharge part 3 stops the suction of the gas and the inert gas supply part 23 supplies the inert gas in the depressurized state in which the pressure in the treatment chamber H1 decreases, the pressure in the treatment chamber H1 increases. Therefore, the gas discharge part 3 and the inert gas supply part 23 constitute a pressure regulator 30 that adjusts the pressure in the treatment chamber H1.

The first concentration discharge part 41 discharges the first concentration liquid in the treatment tank Tk0. In the example of FIG. 1, the first concentration discharge part 41 includes a tank valve 410, a first discharge pipe 411, and a discharge valve 412. The tank valve 410 is provided at the bottom of the treatment tank Tk0, and switches opening and closing of the bottom of the treatment tank Tk0. The upstream end portion of the first discharge pipe 411 is connected to the bottom of the chamber 1a. In the example of FIG. 1, the upstream end portion of the first discharge pipe 411 is connected to the bottom of the chamber 1a at a position facing the tank valve 410 in the vertical direction. The discharge valve 412 is inserted in the first discharge pipe 411.

The controller 6 opens the tank valve 410 and the discharge valve 412 after the discharge of the second concentration liquid by the second concentration discharge part 42. As a result, the first concentration liquid flows out from the bottom of the treatment tank Tk0 and flows into the upstream end portion of the first discharge pipe 411. The first concentration liquid is discharged to the outside through the first discharge pipe 411.

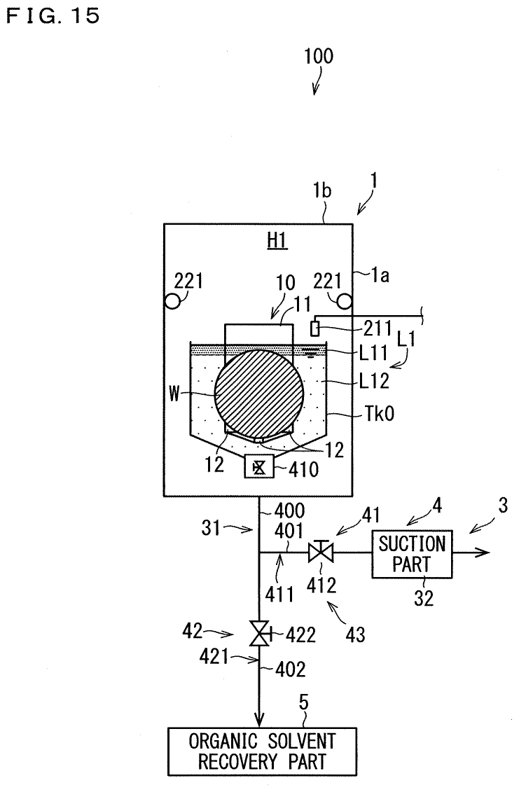

Although different from FIG. 1, the upstream portion of the first discharge pipe 411 and the upstream portion of the discharge pipe 31 may be common. For example, the suction part 32 may be interposed in the first discharge pipe 411 in FIG. 1 (see also FIG. 15). In this case, the first discharge pipe 411 also functions as the discharge pipe 31 for discharging gas. A gas-liquid separator may be provided in the first discharge pipe 411 on the downstream side of the suction part 32. The gas from the treatment chamber H1 and the first concentration liquid from the treatment tank Tk0 flowing into the first discharge pipe 411 are sent to the downstream side by the suction part 32 and flow into the gas-liquid separator. The gas-liquid separator separates the gas and the first concentration liquid, and discharges each of the gas and the first concentration liquid to the outside through another discharge pipe.

### Operation Example of Processing Unit 1

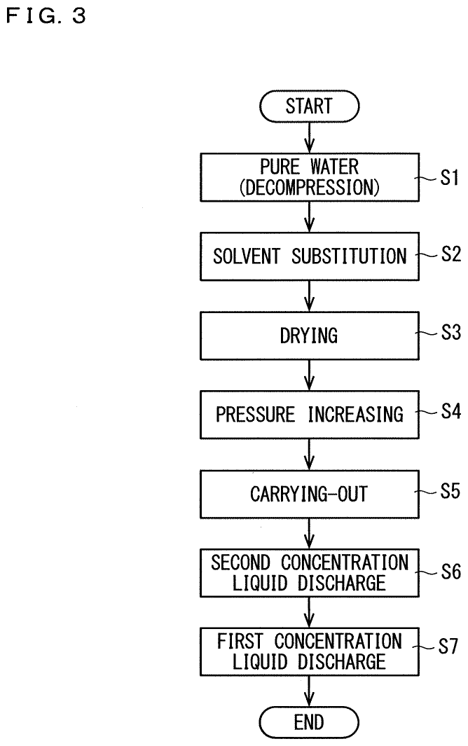

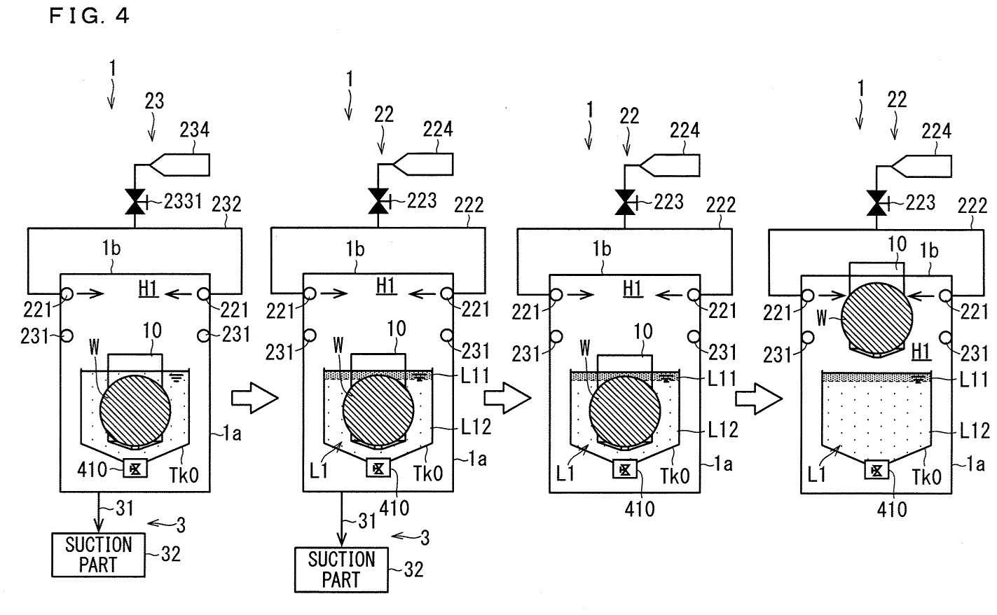

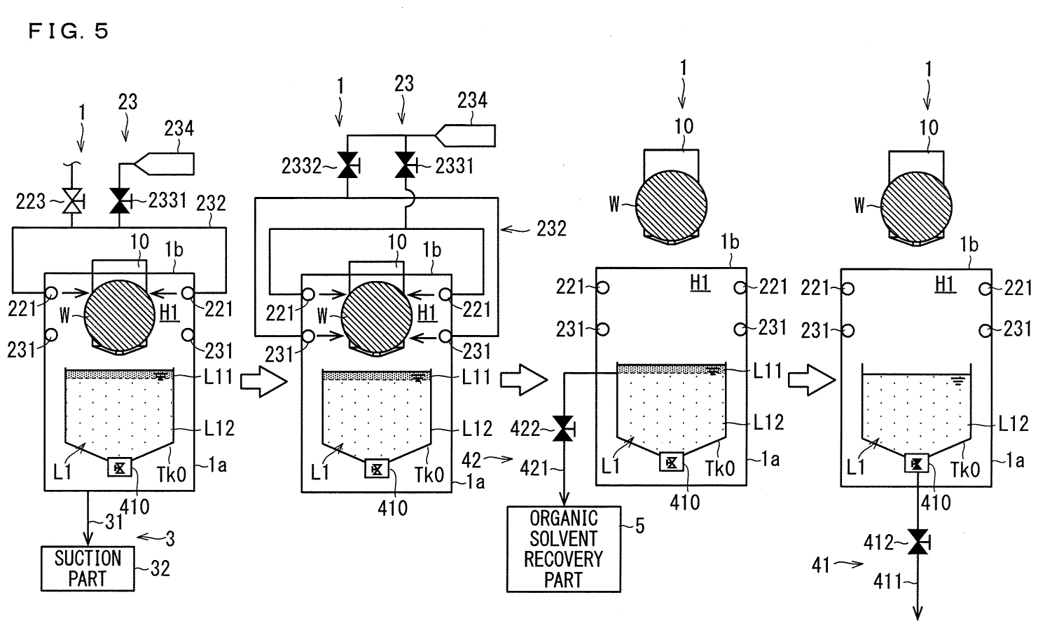

FIG. 3 is a flowchart illustrating an example of processing of the substrate W by the processing unit 1 according to the first embodiment. This processing is executed by the controller 6 controlling various configurations of the substrate processing apparatus 100. FIGS. 4 and 5 are diagrams each illustrating an example of a temporal change of the state of the processing unit 1. In FIGS. 4 and 5, the fact that the valve is open is indicated by a black valve. Here, initially, the controller 6 causes the inert gas supply part 23 to eject the inert gas from the ejection pipe 221.

First, the processing unit 1 performs pure water treatment on the plurality of substrates W (step S1: pure water process). Specifically, the controller 6 causes the pure water supply part 21 to supply pure water to the treatment tank Tk0, and causes the substrate holder 10 to lower the plurality of substrates W to the immersion position to immerse the plurality of substrates W in pure water. For example, first, the controller 6 opens the supply valve 213 to store the pure water in the treatment tank Tk0. Next, the controller 6 opens the lid 1b and causes the substrate holder 10 to lower the plurality of substrates W from the position above the treatment chamber H1 to the immersion position. As a result, as illustrated first from the left in FIG. 4, the plurality of substrates W are immersed in pure water in the treatment tank Tk0. Then, the controller 6 closes the lid 1b.

Here, it is assumed that chemical liquid or particles adhere to the main surface of each substrate W by pretreatment. When the plurality of substrates W are immersed in pure water, the chemical liquid or particles adhering to the plurality of substrates W move into pure water with the lapse of time. As a result, the chemical liquid or the particles are gradually removed from the substrate W.

In addition, as an example, the controller 6 causes the gas discharge part 3 to discharge the gas in the treatment chamber H1. Specifically, the controller 6 operates the suction part 32. As a result, the gas in the treatment chamber H1 is supplied to the suction part 32.

The processing unit 1 immerses the substrate W until the chemical liquid or the particles are sufficiently removed from the substrate W, that is, until the pure water treatment is sufficiently performed. For example, the controller 6 may determine that the chemical liquid or the particles are sufficiently removed from the substrate W when the elapsed time from reaching the immersion position of the substrate W becomes equal to or longer than a predetermined pure water reference time. The pure water reference time is set to be equal to or longer than the time required for sufficiently removing the chemical liquid or the particles from the substrate W, and is set to, for example, about 30 seconds to 60 seconds.

When the pure water treatment is sufficiently performed, the processing unit 1 changes the state of the main surface of the substrate W from the state of being immersed in pure water to the state in which the organic solvent adheres thereto by the treatment to be described later (step S2: solvent substitution step). Here, the organic solvent has higher volatility than pure water. The organic solvent may have a lower surface tension than pure water. The organic solvent is, for example, IPA.

First, the controller 6 causes the solvent vapor supply part 22 to supply vapor of an organic solvent into the treatment chamber H1 in an immersion state in which the plurality of substrates W are immersed in pure water in the treatment tank Tk0. Specifically, as illustrated second from the left in FIG. 4, the controller 6 opens the supply valve 223 to operate the solvent vapor generator 224. As a result, the vapor of the organic solvent is ejected from the ejection pipe 221 into the treatment chamber H1. This vapor moves downward by suction of the suction part 32. A part of the vapor of the organic solvent reaches the liquid surface of the pure water in the treatment tank Tk0 and condenses. As a result, a liquid membrane of the organic solvent is formed on the liquid surface of the pure water in the treatment tank Tk0. That is, the liquid L1 containing water and an organic solvent is stored in the treatment tank Tk0, and the high concentration portion L11 and the low concentration portion L12 are formed in the liquid L1.

Next, as illustrated third from the left in FIG. 4, the controller 6 causes the gas discharge part 3 to temporarily interrupt suction of the gas in the treatment chamber H1. That is, the controller 6 stops the suction part 32.

In a state where the liquid membrane of the organic solvent (for example, the high concentration portion L11) is formed with a sufficient thickness, the controller 6 causes the substrate holder 10 to raise the plurality of substrates W to the drying position. Specifically, the controller 6 may cause the substrate holder 10 to raise the plurality of substrates W when the elapsed time from the start of supply of the vapor of the organic solvent becomes equal to or longer than a predetermined membrane reference time. The membrane reference time is set to be equal to or longer than the time required for forming a liquid membrane of an organic solvent having a sufficient thickness, and is set to, for example, about 5 seconds to 10 seconds.

As the substrates W rise, the plurality of substrates W pass through the high concentration portion L11. By this passage, the organic solvent adheres to the main surface of the substrate W. Therefore, after the plurality of substrates W are raised to the drying position, the organic solvent adheres to most of the main surfaces of the substrates W. However, immediately after reaching the drying position, pure water may remain on the main surface of the substrate W. In this case, as illustrated fourth from the left in FIG. 4, the processing unit 1 may leave the substrate W at the drying position for a predetermined substitution time. In the example of FIG. 4, the ejection pipe 221 continues to eject the vapor of the organic solvent toward the substrate W. A part of the vapor of the organic solvent in the treatment chamber H1 is condensed on the main surfaces of the plurality of substrates W, the organic solvent is substituted for residual pure water, and the residual pure water flows down from the substrates W. The substitution time is set to be equal to or longer than the time required for sufficient substitution from pure water to the organic solvent, and is set to, for example, about 10 seconds to 50 seconds. Since the volatility of the organic solvent is higher than the volatility of water, drying of the substrate W described later can be quickly performed.

When the pure water on the main surface of the substrate W is sufficiently substituted for the organic solvent, the processing unit 1 dries the plurality of substrates W (step S3: drying step). Specifically, the controller 6 causes the solvent vapor supply part 22 to stop the supply of the vapor of the organic solvent, causes the inert gas supply part 23 to supply the inert gas, and causes the gas discharge part 3 to suck the gas in the treatment chamber H1. For example, as illustrated first from the left in FIG. 5, the controller 6 closes the supply valve 223 and opens the supply valve 2331. As a result, the inert gas is ejected from the ejection pipe 221 into the treatment chamber H1. In the example of FIG. 5, the ejection pipe 221 is aligned in the horizontal direction with the substrate W located at the stop position, and ejects the inert gas toward the substrate W. The inert gas supply part 23 may supply a high-temperature inert gas. For example, a heater may be provided in the supply pipe 232 of the inert gas supply part 23.

In addition, the controller 6 operates the suction part 32. As a result, the gas in the treatment chamber H1 is discharged through the discharge pipe 31. The gas discharge part 3 adjusts the pressure in the treatment chamber H1 to a first pressure value suitable for drying the substrate W. That is, the processing unit 1 dries the plurality of substrates W while reducing the pressure in the treatment chamber H1 to the first pressure value. This promotes evaporation of the organic solvent. That is, the processing unit 1 can quickly dry the substrate W.

When the substrate W is sufficiently dried, the processing unit 1 increases the pressure in the treatment chamber H1 (step S4: pressure increasing step). For example, the controller 6 may determine that the substrate W is sufficiently dried when the elapsed time from the start of supply of the inert gas becomes equal to or longer than a predetermined drying reference time. The drying reference time is set to be equal to or longer than the time required for drying the substrate W, and is set to, for example, about 40 seconds to 80 seconds.

The controller 6 causes the pressure regulator 30 to increase the pressure in the treatment chamber H1. Specifically, the controller 6 causes the gas discharge part 3 to stop suction of the gas in the treatment chamber H1. The controller 6 may cause the inert gas supply part 23 to increase the flow rate of the inert gas. For example, as illustrated second from the left in FIG. 5, the controller 6 also opens the supply valve 2332. As a result, the inert gas is supplied into the treatment chamber H1 from both the ejection pipe 221 and the ejection pipe 231. The controller 6 causes the inert gas supply part 23 to supply the inert gas so that the pressure in the treatment chamber H1 becomes a second pressure value larger than the first pressure value. The second pressure value is a value closer to the standard atmospheric pressure than the first pressure value.

Next, the controller 6 opens the lid 1b and causes the substrate holder 10 to raise the plurality of substrates W to a position above the treatment chamber H1 (step S5: carrying-out step). As a result, as illustrated third from the left in FIG. 5, the plurality of treated substrates W are carried out from the treatment chamber H1.

Next, the second concentration discharge part 42 discharges the second concentration liquid from the treatment tank Tk0, and supplies the second concentration liquid to the organic solvent recovery part 5 (step S6: second concentration liquid discharge step). That is, the discharge part 4 discharges the second concentration liquid in a non-immersion state in which the plurality of substrates W are located above the treatment tank Tk0. Specifically, as shown third from the left in FIG. 5, the controller 6 opens the discharge valve 422. In a case where the liquid feeder 423 is provided, the controller 6 operates the liquid feeder 423. As a result, the liquid L1 flowing into the upstream end portion of the second discharge pipe 421 in the treatment tank Tk0 is supplied as the second concentration liquid to the organic solvent recovery part 5 through the second discharge pipe 421. A portion of the liquid L1 generally above the upstream end portion flows into the upstream end portion of the second discharge pipe 421. In other words, a portion of the liquid L1 below the upstream end portion of the second discharge pipe 421 does not flow much into the second discharge pipe 421 and remains in the treatment tank Tk0. That is, the discharge part 4 (specifically, the second concentration discharge part 42) supplies the second concentration liquid to the organic solvent recovery part 5 while avoiding at least a part of the first concentration liquid in the treatment tank Tk0.

When the second concentration liquid is sufficiently discharged, the second concentration discharge part 42 stops discharging the second concentration liquid. For example, the controller 6 closes the discharge valve 412 when the elapsed time from the time of opening the discharge valve 422 becomes equal to or longer than a predetermined second discharge reference time. The second discharge reference time is set in advance to be equal to or longer than the time required for discharging the second concentration liquid. The controller 6 stops the liquid feeder 423 as necessary. By discharging the second concentration liquid, substantially only the first concentration liquid is stored in the treatment tank Tk0.

Next, the first concentration discharge part 41 discharges the first concentration liquid from the treatment tank Tk0 (step S7: first concentration liquid discharge step). Specifically, as shown fourth from the left in FIG. 5, the controller 6 opens the tank valve 410 and the discharge valve 412. As a result, the first concentration liquid flows out into the chamber 1a through the bottom (tank valve 410) of the treatment tank Tk0 and flows into the upstream end portion of the first discharge pipe 411 connected to the bottom of the chamber 1a. The first concentration liquid is discharged to the outside through the first discharge pipe 411. When the first concentration liquid is sufficiently discharged, the first concentration discharge part 41 stops discharging the first concentration liquid. For example, the controller 6 closes the tank valve 410 and the discharge valve 412 when the elapsed time from the time of opening the tank valve 410 and the discharge valve 412 becomes equal to or longer than a predetermined first discharge reference time. The first discharge reference time is set in advance to be equal to or longer than the time required for discharging the first concentration liquid.

As described above, the processing unit 1 can perform pure water treatment on the plurality of substrates W. Moreover, in the above-described example, the processing unit 1 condenses the vapor of the organic solvent on the liquid surface of the pure water in the treatment tank Tk0 to form a liquid membrane of the organic solvent on the liquid surface of the pure water. Therefore, a concentration distribution in which the solvent concentration is high is formed on the upper side in the liquid L1 in the treatment tank Tk0. That is, the high concentration portion L11 and the low concentration portion L12 are formed in the liquid L1 in the treatment tank Tk0 in the immersion state in which the substrate W is immersed in the pure water in the treatment tank Tk0. Therefore, after the treatment of the substrate W, almost no standing time for forming the high concentration portion L11 and the low concentration portion L12 is required, and the discharge of the second concentration liquid from the treatment tank Tk0 can be executed at an earlier timing after the treatment of the substrate W is completed. As a result, the discharge of the first concentration liquid can also be terminated at an earlier timing. Therefore, the processing unit 1 can treat the next plurality of substrates W at an earlier timing. That is, the throughput of the processing unit 1 can be improved.

In addition, in the above-described example, the second concentration discharge part 42 discharges the second concentration liquid from the treatment tank Tk0 (step S6) after the pressure in the treatment chamber H1 is increased by the pressure regulator 30 (step S4). That is, the controller 6 causes the discharge part 4 to discharge the second concentration liquid from the treatment tank Tk0 while causing the pressure regulator 30 to adjust the pressure in the treatment chamber H1 to the second pressure value. As a result, at the time of discharging the second concentration liquid, a relatively high pressure can be applied to the liquid surface of the treatment tank Tk0 by the gas in the treatment chamber H1. Therefore, the second concentration discharge part 42 can more quickly discharge the second concentration liquid.

Note that the second concentration discharge part 42 does not necessarily start discharging the second concentration liquid from the treatment tank Tk0 after carrying out the substrate W (step S5). The second concentration discharge part 42 may start discharging the second concentration liquid from the treatment tank Tk0 before carrying out the substrate W. As an example, the second concentration discharge part 42 may start discharging the second concentration liquid when the pressure in the treatment chamber H1 becomes equal to or higher than a predetermined pressure reference value. For example, the pressure reference value is set in advance to a value larger than the first pressure value.

### Organic Solvent Recovery Part 5

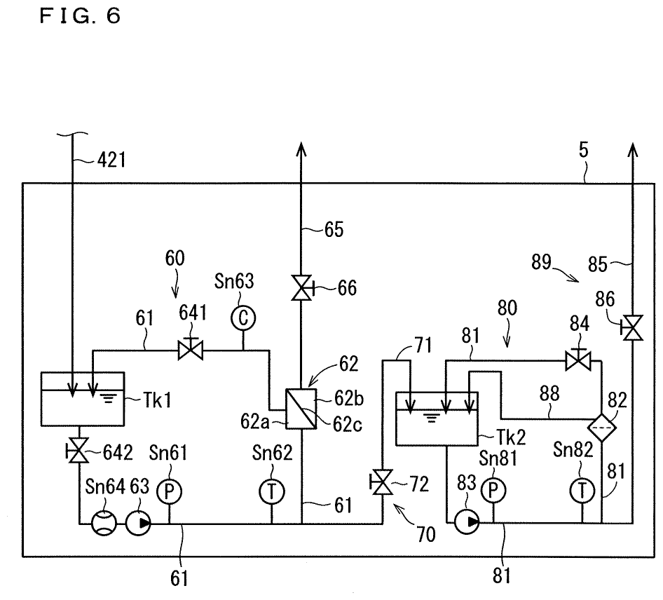

Next, an example of the organic solvent recovery part 5 will be described. The organic solvent recovery part 5 can be provided below the floor where the processing unit 1 is provided. FIG. 6 is a diagram schematically showing an example of the organic solvent recovery part 5. In the example of FIG. 6, the organic solvent recovery part 5 includes a recovery tank Tk1, a dehydration circulation part 60, a purification circulation part 80, and a liquid feeding pipe 85. The second concentration liquid flows into the recovery tank Tk1 through the second discharge pipe 421. That is, the second concentration liquid is recovered in the recovery tank Tk1.

The dehydration circulation part 60 includes a dehydration circulation pipe 61 and a dewaterer 62. The dehydration circulation pipe 61 is connected to the recovery tank Tk1. The dehydration circulation pipe 61 is a pipe for returning the second concentration liquid from the recovery tank Tk1 to the recovery tank Tk1.

A dewatering-side liquid feeding pump 63, a first switching valve 641, and a second switching valve 642 are interposed in the dehydration circulation pipe 61. As an example, the dewatering-side liquid feeding pump 63 is provided at a position on the upstream side of the dewaterer 62 to be described later, the first switching valve 641 is provided at a position on the downstream side of the dewaterer 62, and the second switching valve 642 is provided at a position on the upstream side of the dewatering-side liquid feeding pump 63.

The dewaterer 62 is interposed in the dehydration circulation pipe 61. Therefore, the second concentration liquid flows into the dewaterer 62. The dewaterer 62 separates water from the second concentration liquid that has flowed in, and causes the water to flow in a separation discharge pipe 65. The separated second concentration liquid is continuously circulated in the dehydration circulation pipe 61. By this dehydration, in the dehydration circulation pipe 61, the concentration of the organic solvent in the second concentration liquid immediately after the dewaterer 62 (hereinafter, referred to as a solvent concentration) becomes higher than the solvent concentration in the second concentration liquid immediately before the dewaterer 62. Since the dehydration circulation part 60 circulates the second concentration liquid through the dehydration circulation pipe 61, the second concentration liquid continues to flow into the dewaterer 62. Therefore, the dewaterer 62 continues to separate water from the second concentration liquid. As a result, the solvent concentration of the second concentration liquid during circulation increases over time. Hereinafter, the second concentration liquid in which the solvent concentration is increased to a predetermined solvent standard value or more is referred to as a third concentration liquid. The dehydration circulation part 60 generates a third concentration liquid by circulating the second concentration liquid.

The dewaterer 62 may be, for example, a distiller, an atomizing separator or a membrane separator. In the example of FIG. 5, the dewaterer 62 includes a membrane separator 621. The membrane separator 621 includes a first path 621a, a second path 621b, and a separation membrane 621c. The first path 621a is interposed in the dehydration circulation pipe 61 and constitutes a part of the dehydration circulation path of the dehydration circulation part 60. Therefore, the second concentration liquid passes through the first path 621a. The separation membrane 621c partitions the first path 621a and the second path 621b. The separation membrane 621c is a membrane that allows water in the second concentration liquid to pass therethrough and substantially blocks the organic solvent. A part of the water in the second concentration liquid flowing into the first path 621a passes through the separation membrane 621c and flows into the second path 621b.

The separation membrane 621c may be a zeolite membrane, an organic separation membrane, or a CNT (carbon nanotube) separation membrane. The zeolite membrane has, for example, a crystal structure in which (SiO₄)⁴⁻ and (AlO₄)⁵⁻ having a tetrahedral structure are mutually connected. The organic separation membrane is, for example, an organic membrane of polyvinyl alcohol, chitosan, polyimide, or the like. The CNT separation membrane is, for example, a membrane obtained by adding carbon nanotubes to a membrane of polyamide or the like. Alternatively, a two-dimensional material may be adopted as the material of the separation membrane 621c. The two-dimensional material is a material composed of one layer of atoms, and may be, for example, molybdenum sulfide (MoS₂) or a composite atomic layer compound of a pre-periodic transition metal (titanium, vanadium, or the like) and a light element (carbon or nitrogen). Alternatively, a metal organic framework (MOF) material or a carbon material (for example, graphene or graphene oxide) may be applied as the material of the separation membrane 621c. Here, a zeolite membrane is applied as the separation membrane 621c.

The upstream end portion of the separation discharge pipe 65 is connected to the second path 621b. The water separated from the second concentration liquid is discharged to the outside (for example, a waste liquid treatment part of the factory equipment) through the separation discharge pipe 65. The separation discharge pipe 65 may be provided with a decompression pump that decompresses the second path 621b. As illustrated in FIG. 5, a discharge valve 66 is interposed in the separation discharge pipe 65.

In the example of FIG. 5, the organic solvent recovery part 5 is provided with a purification tank Tk2. The purification tank Tk2 is connected to the recovery tank Tk1 through a first liquid feeding pipe 71, and receives the third concentration liquid from the recovery tank Tk1 through the first liquid feeding pipe 71. As an example, the downstream end portion of the first liquid feeding pipe 71 is connected to the purification tank Tk2, and the upstream end portion of the first liquid feeding pipe 71 is connected to the dehydration circulation pipe 61. The upstream end portion of the first liquid feeding pipe 71 is connected to the dehydration circulation pipe 61 at a position between the dewatering-side liquid feeding pump 63 and the first switching valve 641. A first liquid feeding valve 72 is interposed in the first liquid feeding pipe 71.

The purification circulation part 80 includes a purification circulation pipe 81 and a filter 82. The purification circulation pipe 81 is a circulation pipe for circulating the third concentration liquid. In the example of FIG. 5, the purification circulation pipe 81 is connected to the purification tank Tk2. The purification circulation pipe 81 is a pipe for returning the third concentration liquid from the purification tank Tk2 to the purification tank Tk2.

A purification-side liquid feeding pump 83 and a switching valve 84 are interposed in the purification circulation pipe 81. As an example, the purification-side liquid feeding pump 83 is provided at a position on the upstream side of the filter 82, and the switching valve 84 is provided at a position on the downstream side of the filter 82.

The filter 82 is interposed in the purification circulation pipe 81. Therefore, the third concentration liquid flows into the filter 82. The filter 82 traps impurities in the third concentration liquid. By this trap, the impurity content in the third concentration liquid immediately before the filter 82 becomes lower than the impurity content in the third concentration liquid immediately after the filter 82. Since the purification circulation part 80 circulates the third concentration liquid through the purification circulation pipe 81, the third concentration liquid continues to flow into the filter 82. Therefore, the filter 82 continues to trap impurities from the third concentration liquid. As a result, the impurity content of the third concentration liquid during circulation decreases with the lapse of time. That is, the cleanliness of the third concentration liquid increases with the lapse of time.

The second liquid feeding pipe 85 is a pipe through which the third concentration liquid with the impurity content reduced by the purification circulation part 80 flows toward the supply tank Tk3. As an example, the downstream end portion of the second liquid feeding pipe 85 is connected to the supply tank Tk3, and the upstream end portion of the second liquid feeding pipe 85 is connected to the purification circulation pipe 81.

As described above, the organic solvent recovery part 5 increases the solvent concentration of the second concentration liquid discharged from the processing unit 1 to generate the third concentration liquid, and then reduces the impurity content of the third concentration liquid. The third concentration liquid with the reduced impurity content is used again in the processing unit 1. That is, the substrate processing apparatus 100 reuses the organic solvent in the second concentration liquid discharged from the processing unit 1. According to this, the amount of the organic solvent to be discarded can be reduced, and the organic solvent can be more effectively used. That is, the organic solvent recovery part 5 contributes to liquid saving.

Moreover, in the above-described example, the dewaterer 62 includes the membrane separator 621. The membrane separator 621 can separate water from the second concentration liquid with low energy.

### Concentration of Second Concentration Liquid

An application range of the solvent concentration may be set in the dewaterer 62. The application range is an application range of the solvent concentration of the liquid flowing into the dewaterer 62. For example, if a fluid with a solvent concentration below the lower limit value of the application range flows into the dewaterer 62, a failure of the dewaterer 62 may occur. For example, the dewaterer 62 cannot sufficiently separate water from the fluid. When the separation membrane 621c is a zeolite membrane, the lower limit value thereof can be about 50 wt %. For example, when the first concentration liquid with a low solvent concentration flows into the zeolite membrane, the zeolite membrane may be damaged.

The solvent concentration of the second concentration liquid may be equal to or more than the lower limit value of the application range of the separation membrane 621c. That is, the upstream end portion of the discharge pipe 421 may be provided at a height position where the average solvent concentration of the second concentration liquid flowing into the upstream end portion is equal to or more than the lower limit value. As a result, the second concentration liquid with a solvent concentration equal to or higher than the lower limit value is stored in the recovery tank Tk1. Therefore, the second concentration liquid with the solvent concentration within the application range flows into the dewaterer 62.

The solvent concentration of the second concentration liquid flowing into the second discharge pipe 421 is not necessarily constant in terms of time. For example, if the upstream end portion of the second discharge pipe 421 is provided at a slightly lower position, the second concentration liquid with a slightly lower solvent concentration initially flows in, and then the second concentration liquid with a higher solvent concentration flows in. As the solvent concentration of the second concentration liquid supplied to the organic solvent recovery part 5, the solvent concentration when the total amount of the liquid L1 flowing into the second discharge pipe 421 is made uniform can be applied.

Although the lower limit value of the application range of the separation membrane 621c is relatively high as described above, the discharge part 4 supplies the second concentration liquid with a high solvent concentration to the organic solvent recovery part 5. Therefore, the separation membrane 621c can appropriately separate water from the second concentration liquid. That is, the separation membrane 621c capable of separating water with low energy can be appropriately used.

### Second Embodiment

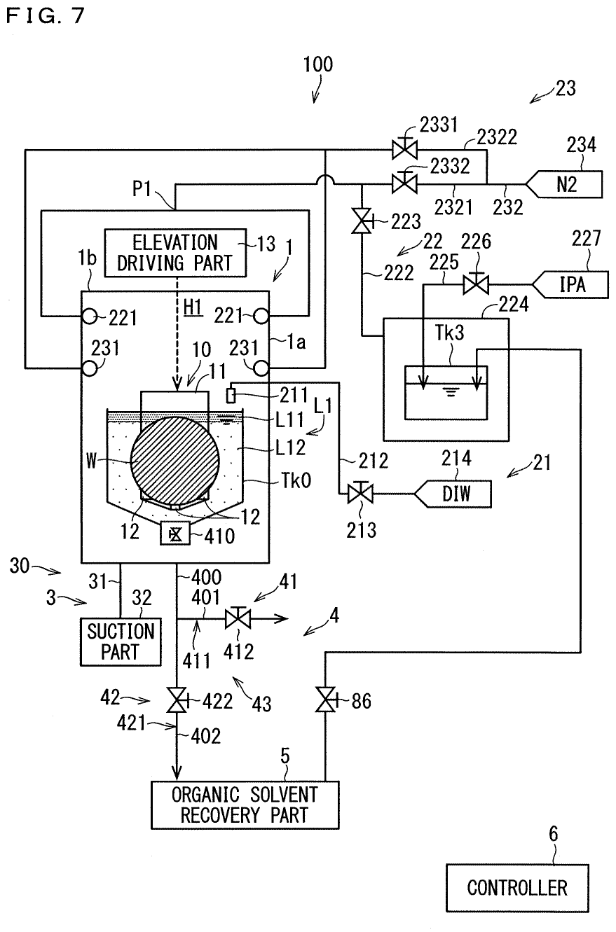

FIG. 7 is a diagram schematically illustrating an example of a substrate processing apparatus 100 according to a first example of the second embodiment. The substrate processing apparatus 100 according to the first example of the second embodiment is different from that of the first embodiment in terms of the specific configuration of the discharge part 4.

The discharge part 4 includes a first discharge pipe 411, a second discharge pipe 421, and a switching valve part 43. In the example of FIG. 7, the first discharge pipe 411 includes a common discharge pipe 400 and a first branch pipe 401, and the second discharge pipe 421 includes a common discharge pipe 400 and a second branch pipe 402. That is, the common discharge pipe 400 is shared by the first discharge pipe 411 and the second discharge pipe 421. The liquid L1 from the bottom of the treatment tank Tk0 flows into the upstream end portion (that is, the upstream end portions of the first discharge pipe 411 and the second discharge pipe 421) of the common discharge pipe 400. It can be said that the first discharge pipe 411 and the second discharge pipe 421 communicate with the bottom of the treatment tank Tk0. In the example of FIG. 7, the upstream end portion of the common discharge pipe 400 is connected to the bottom of the chamber 1a at a position facing the tank valve 410 in the vertical direction. The downstream end portion of the common discharge pipe 400 is connected to the upstream end portions of the first branch pipe 401 and the second branch pipe 402. The downstream end portion of the first branch pipe 401 is connected to, for example, the outside, and the downstream end portion of the second branch pipe 402 is connected to the organic solvent recovery part 5 (for example, the recovery tank Tk1).

The switching valve part 43 switches between a first state in which the liquid L1 from the treatment tank Tk0 flows to the first discharge pipe 411 and a second state in which the liquid L1 from the treatment tank Tk0 flows to the second discharge pipe 421. In the example of FIG. 7, the switching valve part 43 includes the discharge valve 412 and the discharge valve 422. The discharge valve 412 is interposed in the first branch pipe 401, and the discharge valve 422 is interposed in the second branch pipe 402.

The controller 6 first causes the switching valve part 43 to select the first state in a state where the liquid L1 is stored in the treatment tank Tk0. Specifically, the controller 6 closes the discharge valve 422 and opens the tank valve 410 and the discharge valve 412. As a result, a lower portion (that is, the first concentration liquid) of the liquid L1 in the treatment tank Tk0 flows out from the tank valve 410 and is discharged to the outside through the first discharge pipe 411. Therefore, the volume of the low concentration portion L12 in the treatment tank Tk0 decreases with the lapse of time. On the other hand, by this discharge, the high concentration portion L11 in the treatment tank Tk0 lowers with the lapse of time, but the volume of the high concentration portion L11 does not substantially change. Therefore, the average value of the solvent concentration of the liquid L1 in the treatment tank Tk0 increases with the lapse of time. Therefore, the average value of the solvent concentration of the liquid L1 in the treatment tank Tk0 is equal to or higher than a predetermined concentration reference value.

When the solvent concentration (average value) of the liquid L1 in the treatment tank Tk0 becomes equal to or higher than the concentration reference value, the controller 6 causes the switching valve part 43 to select the second state. Specifically, the controller 6 closes the discharge valve 412 and opens the discharge valve 422. As a result, the second concentration liquid in the treatment tank Tk0 is supplied to the organic solvent recovery part 5 through the second discharge pipe 421.

As a condition for switching from the first state to the second state by the switching valve part 43, for example, a condition using time may be applied. For example, the controller 6 may cause the switching valve part 43 to execute switching from the first state to the second state when the elapsed time from the start of discharging the liquid L1 in the treatment tank Tk0 becomes equal to or longer than a predetermined switching reference time. The switching reference time can be set in advance to a time required for the solvent concentration (average value) of the liquid L1 in the treatment tank Tk0 to become the concentration reference value.

Alternatively, a condition using the storage amount of the liquid L1 in the treatment tank Tk0 may be applied as the switching condition. The storage amount of the liquid L1 can be detected by a sensor (not illustrated) (for example, a liquid level sensor). The controller 6 may cause the switching valve part 43 to execute switching from the first state to the second state when the storage amount detected by the sensor becomes equal to or less than a predetermined storage reference value. The storage reference value can be set in advance to the storage amount when the solvent concentration (average value) of the liquid L1 in the treatment tank Tk0 becomes the concentration reference value.

### Operation Example of Processing Unit 1

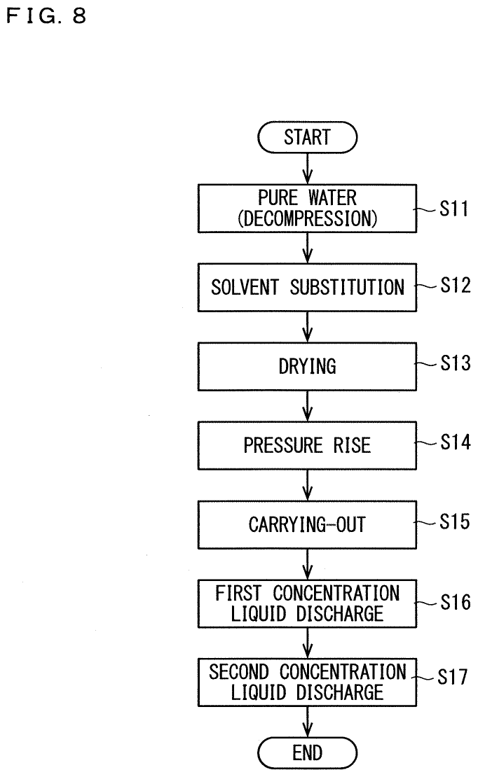

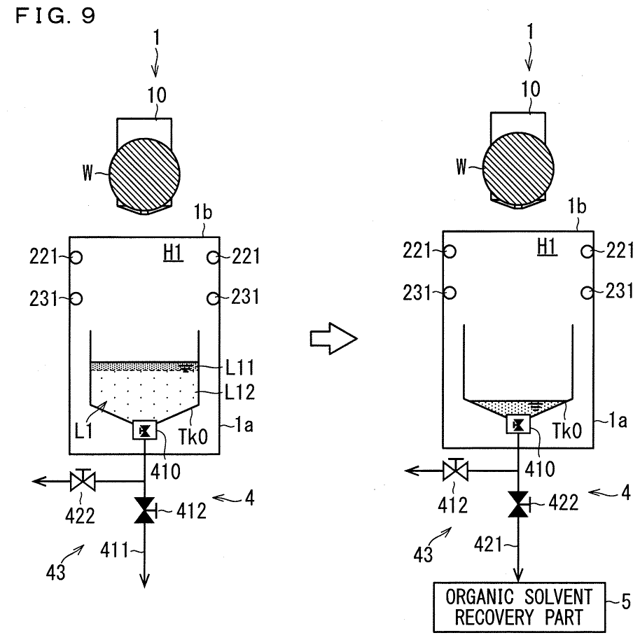

FIG. 8 is a flowchart illustrating an example of the operation of the processing unit 1 according to the first example of the second embodiment. Steps S11 to S15 are similar to steps S1 to S5 of the first embodiment, respectively. In the example of FIG. 8, after completion of step S15 (discharge step), the discharge part 4 first discharges the first concentration liquid from the treatment tank Tk0 (step S16: first concentration liquid discharge step), and then discharges the second concentration liquid from the treatment tank Tk0 (step S17: second concentration liquid discharge step). FIG. 9 is a diagram illustrating an example of a temporal change of the state of the processing unit 1 in steps S16 and S17.

First, the switching valve part 43 selects the first state. Specifically, as shown first from the left in FIG. 9, the controller 6 closes the discharge valve 422 and opens the tank valve 410 and the discharge valve 412. As a result, a lower portion (that is, the first concentration liquid) of the liquid L1 in the treatment tank Tk0 flows out from the tank valve 410 and is discharged to the outside through the first discharge pipe 411.

By this discharge, the solvent concentration (average value) of the liquid L1 in the treatment tank Tk0 increases with the lapse of time. When the solvent concentration (average value) of the liquid L1 in the treatment tank Tk0 becomes equal to or higher than the concentration reference value, the controller 6 causes the switching valve part 43 to select the second state (step S17). Specifically, as illustrated second from the left in FIG. 9, the controller 6 closes the discharge valve 412 and opens the discharge valve 422. As a result, the second concentration liquid in the treatment tank Tk0 is supplied to the organic solvent recovery part 5 through the second discharge pipe 421.

As described above, the discharge part 4 can discharge the first concentration liquid and the second concentration liquid separately from the bottom of the treatment tank Tk0. Then, the discharge part 4 supplies the second concentration liquid to the organic solvent recovery part 5 while avoiding the first concentration liquid. Therefore, as in the first embodiment, the organic solvent recovery part 5 can generate the third concentration liquid in a short time and with low energy.

In the first example of the second embodiment, the liquid L1 remaining in the treatment tank Tk0 after the discharge of the first concentration liquid (step S16) is supplied to the organic solvent recovery part 5 as the second concentration liquid (step S17). That is, the solvent concentration of the second concentration liquid depends on the discharge amount of the liquid L1 (first concentration liquid) discharged through the first discharge pipe 411. As the discharge amount of the first concentration liquid increases, the solvent concentration of the second concentration liquid increases. Therefore, the solvent concentration of the second concentration liquid can be easily adjusted by adjusting the timing at which the switching valve part 43 switches from the first state to the second state. For example, the lower limit value of the application range of the dewaterer 62 may be changed due to replacement of the dewaterer 62, aging, or the like. Even in this case, the discharge part 4 can easily supply the second concentration liquid with a solvent concentration equal to or higher than the lower limit value of the application range to the organic solvent recovery part 5 by adjusting the switching timing of the switching valve part 43.

The flow rate of the liquid L1 passing through the tank valve 410 may be larger than the flow rate of the liquid L1 flowing into the upstream end portion of the common discharge pipe 400. In this case, a part of the liquid L1 flowing out of the tank valve 410 flows into the upstream end portion of the common discharge pipe 400 while staying at the bottom of the chamber 1a. When the switching valve part 43 switches the first state to the second state in a state where the first concentration liquid stays at the bottom of the chamber 1a, the second concentration liquid from the bottom of the treatment tank Tk0 joins the first concentration liquid at the bottom of the chamber 1a. By this joining, the solvent concentration of the second concentration liquid decreases.

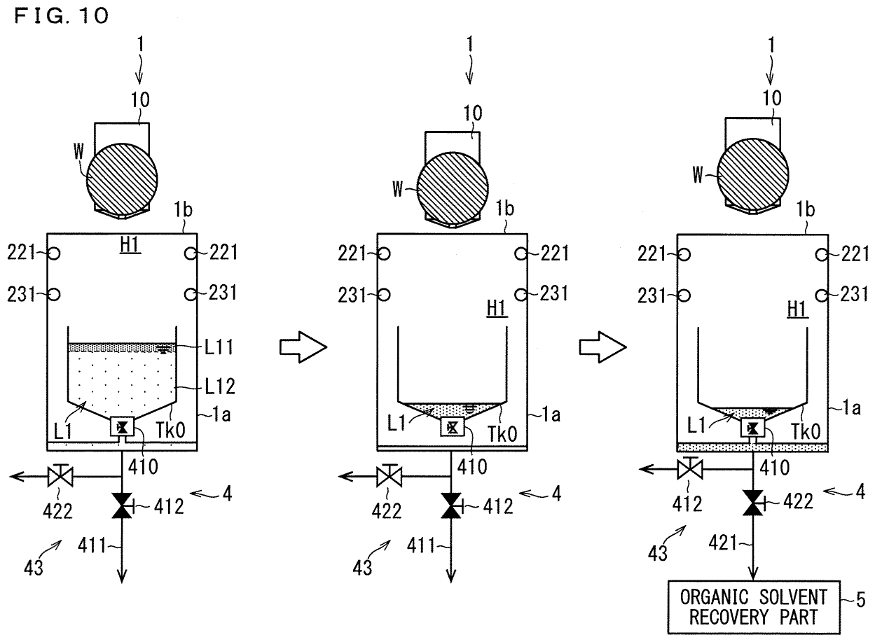

Therefore, the switching valve part 43 may temporarily close the tank valve 410 when switching the first state to the second state. FIG. 10 is a diagram illustrating an example of a temporal change of the state of the processing unit 1 that discharges the liquid L1 from the treatment tank Tk0. As illustrated first from the left in FIG. 10, the discharge part 4 first discharges the first concentration liquid from the treatment tank Tk0. Specifically, the controller 6 closes the discharge valve 422 and opens the tank valve 410 and the discharge valve 412. Here, the outflow flow rate of the liquid L1 from the bottom (tank valve 410) of the treatment tank Tk0 is larger than the inflow flow rate of the liquid L1 to the upstream end portion of the first discharge pipe 411. For example, the channel area of the tank valve 410 is larger than the channel area of the upstream end portion of the first discharge pipe 411. Therefore, as illustrated first from the left in FIG. 10, the first concentration liquid is discharged through the first discharge pipe 411 while the first concentration liquid stays at the bottom in the chamber 1a.

When the solvent concentration (average value) of the liquid L1 in the treatment tank Tk0 becomes equal to or higher than the concentration reference value, the controller 6 causes the switching valve part 43 to interrupt the discharge from the treatment tank Tk0. Specifically, as illustrated second from the left in FIG. 10, the controller 6 closes the tank valve 410. As a result, the second concentration liquid is not discharged from the treatment tank Tk0, and the first concentration liquid staying at the bottom in the chamber 1a is discharged through the first discharge pipe 411.

When the discharge of the first concentration liquid in the chamber 1a is finished, the controller 6 causes the switching valve part 43 to select the second state. For example, the controller 6 may determine that the discharge of the first concentration liquid in the chamber 1a has ended when the elapsed time from the closing of the tank valve 410 becomes equal to or longer than a predetermined discharge reference time. The discharge reference time is set in advance to be equal to or longer than the time required for discharging the first concentration liquid in the chamber 1a, for example.

The controller 6 closes the discharge valve 412 and opens the tank valve 410 and the discharge valve 422 as illustrated third from the left in FIG. 10. As a result, the second concentration liquid in the treatment tank Tk0 is supplied to the organic solvent recovery part 5 through the tank valve 410 and the second discharge pipe 421.

As described above, the switching valve part 43 selects the second state from the first state via the interrupted state in which the tank valve 410 is closed. Therefore, the discharge part 4 can discharge the second concentration liquid from the bottom of the treatment tank Tk0 in a state where the first concentration liquid in the chamber 1a is substantially discharged. Therefore, the discharge part 4 can supply the second concentration liquid to the organic solvent recovery part 5 while suppressing a decrease in the solvent concentration of the second concentration liquid.

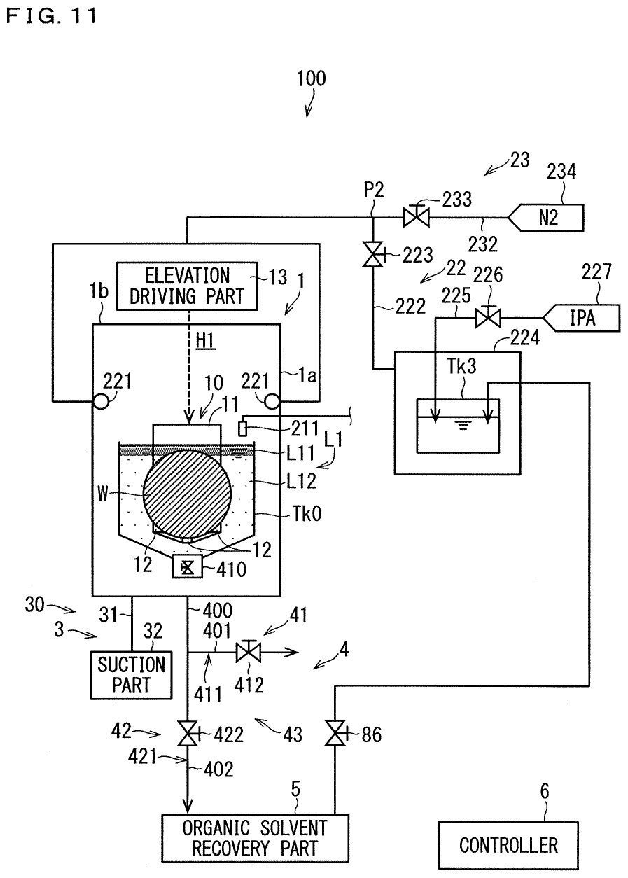

FIG. 11 is a diagram schematically illustrating an example of a substrate processing apparatus 100 according to a second example of the second embodiment. The substrate processing apparatus 100 according to the second example is different from the substrate processing apparatus 100 according to the first example in terms of the configuration of the processing unit 1. In the second example, the ejection pipe 231 is not provided in the processing unit 1. In the second example, the downstream end portion of the supply pipe 232 of the inert gas supply part 23 is connected to the supply pipe 222 at a position P2 on the downstream side of the supply valve 223 of the solvent vapor supply part 22. A supply valve 233 is interposed in the supply pipe 232. As an example, the ejecting direction of the ejection pipe 221 is different from that of the first example. As an example, the ejecting direction of the ejection pipe 221 is the upper side in the vertical direction.

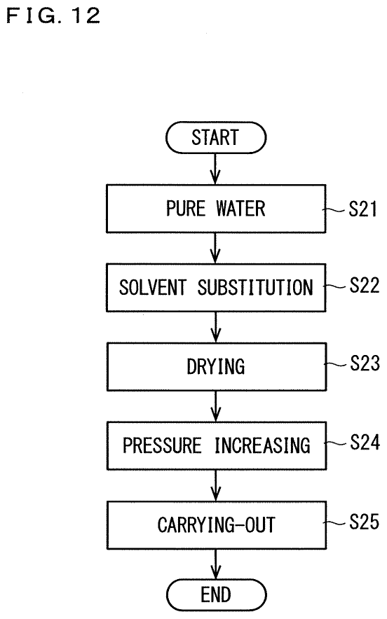

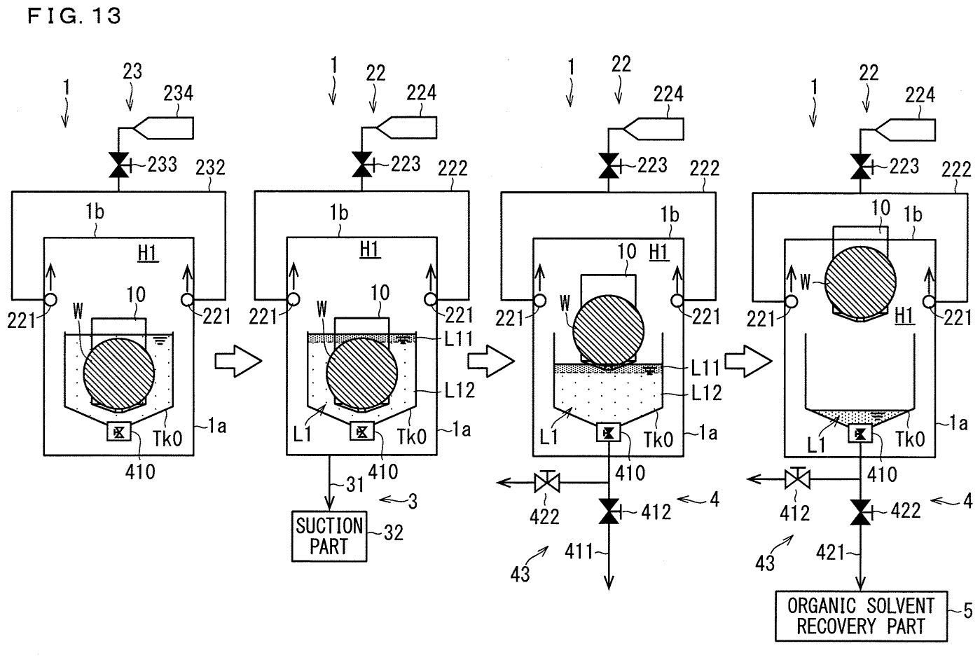

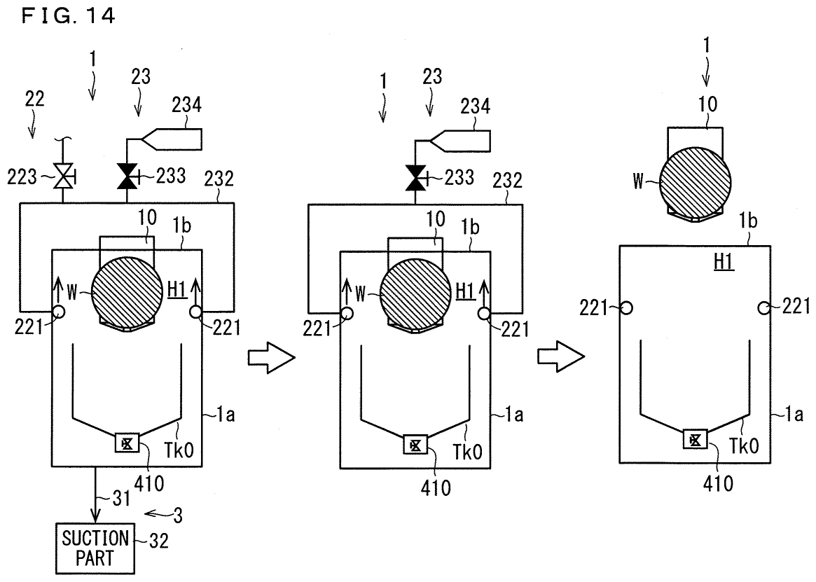

FIG. 12 is a flowchart illustrating an operation example of the substrate processing apparatus 100 according to the second example. FIGS. 13 and 14 are diagrams each illustrating an example of a temporal change of the state of the processing unit 1 according to the second example. It is assumed that the controller 6 initially causes the inert gas supply part 23 to supply the inert gas.

Similarly to step S1, the processing unit 1 performs pure water treatment on the plurality of substrates W (step S21: pure water process). Specifically, the controller 6 causes the pure water supply part 21 to supply pure water to the treatment tank Tk0, and causes the substrate holder 10 to lower the plurality of substrates W to the immersion position to immerse the plurality of substrates W in pure water. As a result, as illustrated first from the left in FIG. 13, the plurality of substrates W are immersed in pure water in the treatment tank Tk0. Then, the controller 6 closes the lid 1b.

When the pure water treatment is sufficiently performed, the processing unit 1 changes the state of the main surface of the substrate W from the state of being immersed in pure water to the state in which the organic solvent adheres thereto by the treatment to be described later (step S22: solvent substitution step). First, the controller 6 causes the solvent vapor supply part 22 to supply vapor of an organic solvent into the treatment chamber H1. Specifically, as shown second from the left in FIG. 13, the controller 6 opens the supply valve 223 to operate the solvent vapor generator 224. As a result, the vapor of the organic solvent is ejected from the ejection pipe 221 into the treatment chamber H1. As an example, the ejection pipe 221 ejects the vapor of the organic solvent toward the upper side in the vertical direction.

Here, the controller 6 operates the suction part 32. Since the vapor ejected from the ejection pipe 221 is sucked by the suction part 32, the vapor makes a U-turn and moves downward in the treatment chamber H1. A part of the vapor reaches the liquid surface of the pure water in the treatment tank Tk0 and condenses. As a result, a liquid membrane of the organic solvent is formed on the liquid surface of the pure water in the treatment tank Tk0. That is, the high concentration portion L11 and the low concentration portion L12 are formed in the liquid L1 in the treatment tank Tk0.

When the liquid membrane is formed with a sufficient thickness, the substrate holder 10 raises the plurality of substrates W. Specifically, as illustrated third from the left in FIG. 13, the controller 6 causes the substrate holder 10 to raise the substrates W. During this rise, the main surface of the substrate W passes through the liquid membrane of the organic solvent. As a result, the organic solvent adheres to the main surface of the substrate W. When the plurality of substrates W reach the drying position, the substrate holder 10 stops the plurality of substrates W at the drying position. The solvent vapor supply part 22 continues to supply vapor of the organic solvent into the treatment chamber H1 even after the plurality of substrates W are stopped. This makes it possible to substitute the pure water remaining on the main surface of the substrate W with the organic solvent.

In addition, as illustrated third from the left in FIG. 13, the discharge part 4 discharges the liquid L1 from the treatment tank Tk0 in parallel with the rise of the substrate W. Specifically, the switching valve part 43 selects the first state. That is, the controller 6 closes the discharge valve 422 and opens the tank valve 410 and the discharge valve 412. As a result, the liquid L1 (here, the first concentration liquid) in the treatment tank Tk0 flows down the tank valve 410 and is discharged through the first discharge pipe 411. By this discharge, the high concentration portion L11 lowers. When the substrate W is raised and the liquid L1 is discharged in parallel in this manner, the substrate W can be pulled up from the liquid L1 more quickly.

When the solvent concentration (average value) of the liquid L1 in the treatment tank Tk0 becomes equal to or higher than the concentration reference value, the discharge part 4 stops the discharge of the first concentration liquid and discharges the second concentration liquid. That is, the switching valve part 43 switches the first state to the second state. Specifically, as shown fourth from the left in FIG. 13, the controller 6 closes the discharge valve 412 and opens the discharge valve 422. As a result, the liquid L1 (that is, the second concentration liquid) in the treatment tank Tk0 is supplied to the organic solvent recovery part 5 through the second discharge pipe 421.

When the pure water on the main surface of the substrate W is sufficiently substituted for the organic solvent, the processing unit 1 dries the plurality of substrates W (step S23: drying step). For example, the solvent vapor supply part 22 stops the supply of the vapor of the organic solvent, the inert gas supply part 23 supplies the inert gas to the treatment chamber H1, and the gas discharge part 3 discharges the gas in the treatment chamber H1. Specifically, as illustrated first from the left in FIG. 14, the controller 6 closes the supply valve 223, opens the supply valve 233, and operates the suction part 32. The gas discharge part 3 adjusts the pressure in the treatment chamber H1 to a first pressure value suitable for drying the substrate W. As a result, the processing unit 1 can quickly dry the substrate W.

When the substrate W is sufficiently dried, the processing unit 1 increases the pressure in the treatment chamber H1 (step S24: pressure increasing step). Specifically, as illustrated second from the left in FIG. 14, the controller 6 stops the operation of the suction part 32. Since the inert gas supply part 23 continues to supply the inert gas into the treatment chamber H1, the pressure in the treatment chamber H1 increases. For example, the inert gas supply part 23 supplies the inert gas such that the pressure in the treatment chamber H1 becomes the second pressure value.

Next, after opening the lid 1b, the processing unit 1 causes the substrate holder 10 to raise the plurality of substrates W to a position above the treatment chamber H1 (step S25; carrying-out step: see also third from the left in FIG. 14).

In the second example of the second embodiment, the first concentration liquid and the second concentration liquid are sequentially discharged from the treatment tank Tk0 while the pure water on the main surface of the substrate W is substituted for the organic solvent (step S22). Therefore, it is not necessary to discharge the first concentration liquid and the second concentration liquid after the drying treatment of the substrate W. Therefore, the next plurality of substrates W can be carried into the processing unit 1 (treatment chamber H1) at an earlier timing. That is, the processing unit 1 can treat the substrate W with a higher throughput.

Meanwhile, in the second example, the first concentration liquid and the second concentration liquid are discharged from the treatment tank Tk0 while the substrate W rises to the drying position. At this time, when the pressure in the treatment chamber H1 is low, it is desirable to provide a liquid feeder (for example, a pump or an ejector) in the first discharge pipe 411 and the second discharge pipe 421. As a result, even when the pressure in the treatment chamber H1 is low, the liquid feeder can promptly feed the first concentration liquid and the second concentration liquid. However, when the liquid feeder is provided in the common discharge pipe 400, the first concentration liquid remaining inside the liquid feeder may be mixed with the second concentration liquid. By providing separate liquid feeders in the first branch pipe 401 and the second branch pipe 402, such joining of the first concentration liquid and the second concentration liquid can be avoided. On the other hand, the manufacturing cost may be increased. Hereinafter, it is intended to promptly discharge the second concentration liquid while reducing the number of liquid feeders.

FIG. 15 is a diagram schematically illustrating a third example of the substrate processing apparatus 100 according to the second embodiment. The substrate processing apparatus 100 according to the third example is different from the substrate processing apparatus 100 according to the second example in terms of the discharge part 4 and the gas discharge part 3. In the third example, the suction part 32 is interposed in the first branch pipe 401. In this configuration, the common discharge pipe 400 and the first branch pipe 401 function as the first discharge pipe 411 and the discharge pipe 31. The suction part 32 is, for example, a water-sealed vacuum pump, and also has a function of feeding the first concentration liquid in the first discharge pipe 411. A gas-liquid separator (not illustrated) can be interposed in the first branch pipe 401 at a position on the downstream side of the suction part 32. The gas-liquid separator separates the first concentration liquid and the gas, and causes the first concentration liquid and the gas to flow through different discharge pipes (not shown).

On the other hand, as illustrated in FIG. 15, the liquid feeder may not be provided in the second discharge pipe 421. The organic solvent recovery part 5 is provided below the bottom of the chamber 1a, and the second concentration liquid in the treatment tank Tk0 flows in the second discharge pipe 421 by its own weight as described later.

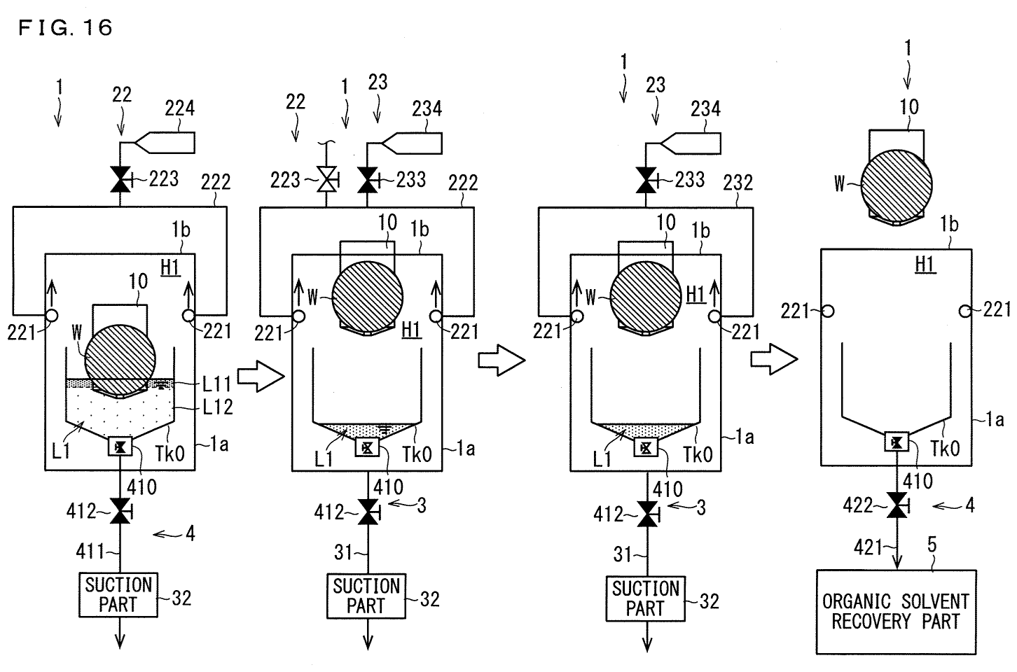

An example of the operation of the processing unit 1 according to the third example is similar to that in FIG. 12. However, the discharge timing of the second concentration liquid is different from that of the second example. FIG. 16 is a diagram showing an example of a temporal change in the state of the processing unit 1 after step S22 (solvent substitution step). As illustrated first from the left in FIG. 16, the substrate holder 10 raises the plurality of substrates W to the drying position, and the discharge part 4 discharges the first concentration liquid from the treatment tank Tk0. Here, although the pressure in the treatment chamber H1 is sufficiently lower than the standard atmospheric pressure, since the controller 6 operates the suction part 32 (liquid feeder), the first concentration liquid can be discharged more quickly.

Then, the discharge part 4 stops discharging the liquid L1 from the treatment tank Tk0 in a state where the second concentration liquid is stored in the treatment tank Tk0. For example, the discharge part 4 stops the discharge of the liquid L1 when the solvent concentration (average value) of the liquid L1 in the treatment tank Tk0 becomes equal to or higher than the concentration reference value. Specifically, the controller 6 closes the tank valve 410.

When the pure water on the main surface of the substrate W is sufficiently substituted for the organic solvent, the processing unit 1 dries the plurality of substrates W (see second from the left in FIG. 16). That is, the processing unit 1 dries the plurality of substrates W in a state where substantially only the second concentration liquid is stored in the treatment tank Tk0. Specifically, the controller 6 closes the supply valve 223, opens the supply valve 233, and operates the suction part 32. The gas discharge part 3 adjusts the pressure in the treatment chamber H1 to a first pressure value.

Then, when the substrate W is sufficiently dried, the processing unit 1 increases the pressure in the treatment chamber H1 (see third from the left in FIG. 16). That is, the processing unit 1 increases the pressure in the treatment chamber H1 in a state where substantially only the second concentration liquid is stored in the treatment tank Tk0. Specifically, the controller 6 stops the suction part 32. As a result, the pressure in the treatment chamber H1 increases with the lapse of time.

Then, in a state where the pressure in the treatment chamber H1 increases to a predetermined pressure reference value or more, the discharge part 4 discharges the second concentration liquid in the treatment tank Tk0 and supplies the second concentration liquid to the organic solvent recovery part 5 (see fourth from the left in FIG. 16). Specifically, the controller 6 opens the tank valve 410 and the discharge valve 422. Since the pressure in the treatment chamber H1 is increased, the discharge part 4 can promptly discharge the second concentration liquid by its own weight, for example. In addition, since the suction part 32 into which the first concentration liquid flows is not provided in the second discharge pipe 421, mixing of the second concentration liquid and the first concentration liquid can also be avoided.

### Third Embodiment

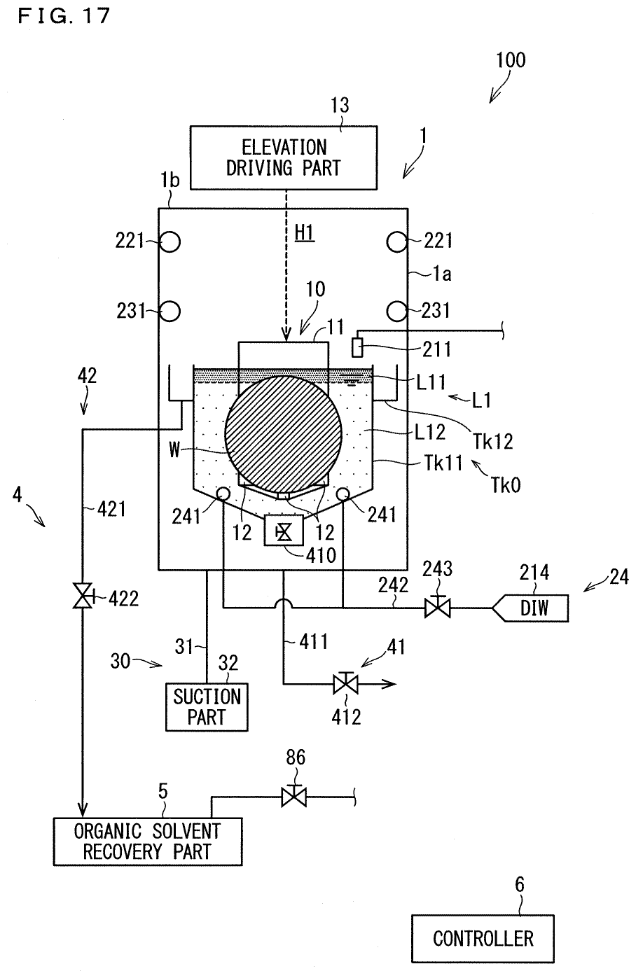

FIG. 17 is a diagram schematically illustrating an example of a substrate processing apparatus 100 according to the third embodiment. The processing unit 1 according to the third embodiment is different from that of the first embodiment in terms of the structure of the treatment tank Tk0 and the configuration of the discharge part 4.

In the third embodiment, the treatment tank Tk0 includes a main body tank Tk11 and an upflow tank Tk12. Liquid is stored in the main body tank Tk11. The plurality of substrates W held by the substrate holder 10 are immersed in the liquid in the main body tank Tk11. The upflow tank Tk12 receives liquid overflowing from the upper portion of the main body tank Tk11. The upflow tank Tk12 includes a bottom and a side wall. The bottom has an annular shape in plan view, and an inner peripheral edge thereof is connected to the side wall of the main body tank Tk11 over the entire circumference. The side wall extends upward from an outer peripheral edge of the bottom.

The discharge part 4 includes an upflow part 24. The upflow part 24 supplies pure water inside the main body tank Tk11 and causes the liquid in the main body tank Tk11 to overflow from the upper portion. The liquid overflowing from the main body tank Tk11 flows into the upflow tank Tk12. The upflow part 24 includes an upflow pipe 241, a supply pipe 242, and a supply valve 243. The upflow pipe 241 is provided at a position to be immersed in the liquid in the main body tank Tk11, and is provided below the plurality of substrates W located at the immersion position in the example of FIG. 17. In the example of FIG. 17, two upflow pipes 241 are provided. The two upflow pipes 241 are arranged in the horizontal direction, and are provided on opposite sides to each other with respect to the center of the substrate W in the horizontal direction. The upflow pipe 241 has an ejection port, and ejects pure water from the ejection port.

The supply pipe 242 is a pipe through which pure water flows toward the upflow pipe 241. The supply pipe 242 branches into two on the downstream side, and each downstream end portion thereof is connected to the upflow pipe 241. The upstream end portion of the supply pipe 242 is connected to the pure water supply source 214. The supply valve 243 is interposed in the supply pipe 242.

The upflow part 24 supplies pure water inside the liquid L1 in a storage state where the liquid L1 is stored in the main body tank Tk11. Specifically, the controller 6 opens the supply valve 243 in the storage state. As a result, pure water is ejected from the upflow pipe 241, and the liquid L1 in the main body tank Tk11 overflows from the upper portion and is received by the upflow tank Tk12. Initially, since the upper portion of the liquid L1, that is, the high concentration portion L11 overflows, the liquid L1 (that is, the second concentration liquid) having a relatively high solvent concentration flows into the upflow tank Tk12.

The upstream end portion of the second discharge pipe 421 is connected to the upflow tank Tk12. In the example of FIG. 17, the upstream end portion of the second discharge pipe 421 is connected to the bottom of the upflow tank Tk12. When the controller 6 opens the discharge valve 422, the second concentration liquid in the upflow tank Tk12 is supplied to the organic solvent recovery part 5 through the second discharge pipe 421.

### Operation Example of Processing Unit 1

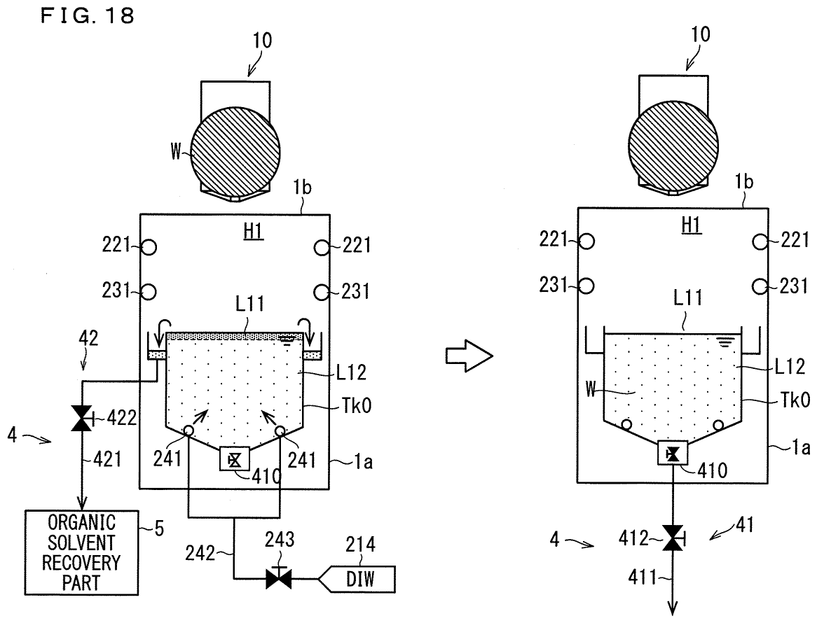

An example of the operation of the processing unit 1 according to the third embodiment is similar to that in FIG. 2 referred to in the first embodiment. However, the specific operation of step S6 is different from that of the first embodiment. FIG. 18 is a diagram schematically illustrating an example of a temporal change of the state of the processing unit 1 in step S6 (second concentration discharge step) according to the third embodiment.

In step S6, as illustrated first from the left in FIG. 18, the upflow part 24 first supplies pure water into the main body tank Tk11. Specifically, the controller 6 opens the supply valve 243. As a result, the pure water is ejected from the upflow pipe 241 into the liquid L1, and the liquid L1 overflows from the upper portion of the main body tank Tk11. The overflowed liquid L1 is received by the upflow tank Tk12. Initially, the high concentration portion L11 overflows.

The discharge part 4 discharges the second concentration liquid in the upflow tank Tk12, and supplies the second concentration liquid to the organic solvent recovery part 5. Specifically, the controller 6 opens the discharge valve 422. As a result, the second concentration liquid in the upflow tank Tk12 is supplied to the organic solvent recovery part 5 through the second discharge pipe 421.

When most of the high concentration portion L11 in the main body tank Tk11 flows into the upflow tank Tk12, the liquid L1 with a low solvent concentration starts to flow into the upflow tank Tk12. Therefore, the average solvent concentration of the liquid L1 flowing into the upflow tank Tk12 decreases with the lapse of time. Therefore, when the solvent concentration (average concentration) of the liquid L1 flowing into the upflow tank Tk12 reaches a predetermined concentration reference value, the upflow part 24 stops the supply of pure water. Specifically, the controller 6 closes the supply valve 243. That is, the upflow part 24 stores the first concentration liquid with a relatively low solvent concentration in the main body tank Tk11 without overflowing from the main body tank Tk11. As a result, the discharge part 4 can supply the second concentration liquid equal to or higher than the concentration reference value to the organic solvent recovery part 5.

For example, the controller 6 may cause the upflow part 24 to stop the supply of the pure water when the elapsed time from the start of the supply of the pure water becomes equal to or longer than a predetermined supply reference time. The supply reference time is set in advance to a time required for discharging the second concentration liquid.

When the discharge of the second concentration liquid is completed, the discharge part 4 discharges the first concentration liquid from the main body tank Tk11 (step S7: first concentration liquid discharge step). Specifically, as illustrated second from the left in FIG. 18, the controller 6 opens the tank valve 410 and the discharge valve 412. As a result, the first concentration liquid in the treatment tank Tk0 is discharged to the outside through the first discharge pipe 411.

As described above, also in the third embodiment, the discharge part 4 can supply the second concentration liquid to the organic solvent recovery part 5 while avoiding at least a part of the first concentration liquid stored in the treatment tank Tk0 (main body tank Tk11). Therefore, as in the first embodiment, the organic solvent recovery part 5 can generate the third concentration liquid in a short time and with low energy.

In the third embodiment, the substrate processing apparatus 100 overflows the second concentration liquid with a relatively high concentration from the main body tank Tk11, and supplies the second concentration liquid to the organic solvent recovery part 5 through the upflow tank Tk12 and the second discharge pipe 421. That is, the solvent concentration of the second concentration liquid depends on the amount of the liquid L1 overflowing from the main body tank Tk11. In other words, the solvent concentration of the second concentration liquid depends on the supply amount of pure water supplied by the discharge part 4. As the supply amount of pure water increases, the solvent concentration of the second concentration liquid decreases. Therefore, the solvent concentration of the second concentration liquid can be easily adjusted by adjusting the supply amount of pure water by the discharge part 4.

As described above, the substrate processing apparatus 100 has been described in detail, but the above description is an example in all aspects, and the present disclosure is not limited thereto. In addition, the various modifications described above can be applied in combination as long as they do not contradict each other. It is understood that many modifications not illustrated can be assumed without departing from the scope of the present disclosure.

The present disclosure includes the following aspects.

A substrate processing apparatus according to a first aspect includes: a treatment tank that stores a liquid; a substrate holder that holds a plurality of substrates and immerses the plurality of substrates in the liquid in the treatment tank; a discharge part that discharges a second concentration liquid having a solvent concentration higher than that of a first concentration liquid, avoiding at least a part of the first concentration liquid in the liquid, from the treatment tank that stores the liquid containing water and an organic solvent having a specific gravity lighter than that of the water in a concentration distribution in which a solvent concentration is higher on an upper side than a lower side; and an organic solvent recovery part including a dewaterer that separates water from the second concentration liquid discharged by the discharge part to generate a third concentration liquid having a solvent concentration higher than that of the second concentration liquid.

A second aspect is the substrate processing apparatus according to the first aspect, including: a pure water supply part including a supply pipe for flowing pure water toward the treatment tank; a solvent vapor supply part including an ejection pipe for ejecting vapor of the organic solvent having higher volatility than the pure water into a space above the treatment tank; and a controller, in which the substrate holder moves up and down the plurality of substrates between an immersion position inside the treatment tank and a position above the treatment tank, and the controller causes the pure water supply part to supply the pure water to the treatment tank and causes the substrate holder to lower the plurality of substrates to the immersion position to immerse the plurality of substrates in the pure water, and in an immersion state in which the plurality of substrates are immersed in the pure water, causing the solvent vapor supply part to eject the vapor from the ejection pipe to form a liquid membrane of the organic solvent on a liquid surface of the treatment tank, raising the plurality of substrates from the immersion position in a state where the liquid membrane is formed, and causing the discharge part to discharge the second concentration liquid from the treatment tank in a non-immersion state where the plurality of substrates are located above the treatment tank.

A third aspect is the substrate processing apparatus according to the second aspect, further including a pressure regulator that adjusts a pressure in a treatment chamber in which the treatment tank is accommodated, in which the controller dries the plurality of substrates in a state of causing the pressure regulator to reduce the pressure in the treatment chamber to a first pressure value, and causes the discharge part to discharge the second concentration liquid from the treatment tank in a state where the pressure regulator adjusts the pressure in the treatment chamber to be higher than the first pressure value.

A fourth aspect is the substrate processing apparatus according to any one of the first to third aspects, in which a solvent concentration of the second concentration liquid is equal to or more than a lower limit value of an application range of a solvent concentration of the dewaterer.

A fifth aspect is the substrate processing apparatus according to the fourth aspect, in which the dewaterer includes a membrane separator having a separation membrane through which water contained in the second concentration liquid passes.

A sixth aspect is the substrate processing apparatus according to any one of the first to fifth aspects, in which the discharge part includes: a discharge pipe having an upstream end portion to be immersed in the liquid in the treatment tank at a height position corresponding to the second concentration liquid; and a downstream end portion connected to the organic solvent recovery part and a discharge valve interposed in the discharge pipe.

A seventh aspect is the substrate processing apparatus according to any one of the first to sixth aspects, in which the discharge part includes: a first discharge pipe communicating with a bottom of the treatment tank; a second discharge pipe communicating with the bottom of the treatment tank and connected to the organic solvent recovery part; a switching valve part that switches between a first state in which the liquid from the bottom of the treatment tank flows through the first discharge pipe and a second state in which the liquid flows through the second discharge pipe; and a controller that causes the switching valve part to select the first state to discharge the first concentration liquid from the bottom of the treatment tank, and then causes the switching valve part to select the second state to discharge the second concentration liquid from the bottom of the treatment tank.

An eighth aspect is the substrate processing apparatus according to the seventh aspect, further including a chamber that accommodates the treatment tank, in which the discharge part further includes a tank valve that switches opening and closing of the bottom of the treatment tank, an upstream end portion of the first discharge pipe is connected to the bottom of the chamber, a flow rate of the liquid flowing out from the bottom of the treatment tank is larger than a flow rate of the liquid flowing into the upstream end portion of the first discharge pipe, and the controller causes the switching valve part to select the second state from the first state via an interrupted state in which the tank valve is closed.

A ninth aspect is the substrate processing apparatus according to the seventh or eighth aspect, including: a pure water supply part that includes a supply pipe, pure water flowing toward the treatment tank through the supply pipe to be stored in the treatment tank; and a solvent vapor supply part that includes an ejection pipe that ejects vapor of the organic solvent having higher volatility than the pure water to a space above the treatment tank, in which the substrate holder moves up and down the plurality of substrates between an immersion position inside the treatment tank and a position above the treatment tank, and the controller causes the pure water supply part to supply the pure water to the treatment tank and causes the substrate holder to lower the plurality of substrates to the immersion position to immerse the plurality of substrates in the pure water, causes the ejection pipe to eject the vapor of the organic solvent in an immersion state in which the plurality of substrates are immersed in the pure water of the treatment tank to form a liquid membrane of the organic solvent on a liquid surface in the treatment tank, and causes the switching valve part to select the first state to cause the liquid in the treatment tank to flow to the first discharge pipe as the first concentration liquid while causing the substrate holder to raise the plurality of substrates in a state in which the liquid membrane is formed.

A tenth aspect is the substrate processing apparatus according to any one of the first to seventh aspects, including a controller, in which the treatment tank includes a main body tank that stores the liquid and an upflow tank that receives the liquid overflowing from an upper portion of the main body tank, the discharge part includes an upflow pipe that is provided at a lower portion in the treatment tank and ejects pure water into the treatment tank to overflow the liquid from the main body tank, and a discharge pipe that includes an upstream end portion connected to the upflow tank and a downstream end portion connected to the organic solvent recovery part, and the controller causes the discharge part to eject the pure water from the upflow pipe to cause the second concentration liquid in the liquid in the treatment tank to flow into the upflow tank and cause the second concentration liquid to be supplied from the upflow tank to the organic solvent recovery part through the discharge pipe.

According to the first aspect, the organic solvent recovery part generates the third concentration liquid from the second concentration liquid having a solvent concentration higher than that of the first concentration liquid. Therefore, the organic solvent recovery part can generate the third concentration liquid in a shorter time as compared with the case of generating the third concentration liquid from the first concentration liquid.

According to the second aspect, the pure water treatment can be performed on the substrate by immersing the substrate in the pure water. By raising the substrate, the main surface of the substrate passes through the liquid membrane of the organic solvent. As a result, the organic solvent can be made to adhere to the main surface of the substrate. Since the organic solvent is easily volatilized, the substrate is easily dried. On the other hand, since the liquid membrane of the organic solvent is formed on the liquid surface of the treatment tank, the liquid is stored in the treatment tank in a concentration distribution in which the solvent concentration becomes high on the upper side. Therefore, the second concentration liquid can be discharged from the treatment tank at an earlier timing after the treatment on the substrate.

According to the third aspect, in a state where the pressure in the treatment chamber is relatively high, a relatively high pressure is applied to the liquid surface of the treatment tank. Therefore, the discharge part can more quickly discharge the second concentration liquid.

According to the fourth aspect, the dewaterer can appropriately separate water from the second concentration liquid.

According to the fifth aspect, water can be separated from the second concentration liquid with low energy. Although the lower limit value of the application range of the separation membrane is relatively high, the discharge part supplies the second concentration liquid having a high solvent concentration to the organic solvent recovery part. Therefore, the separation membrane can appropriately separate water from the second concentration liquid. That is, a separation membrane capable of separating water with low energy can be appropriately used.

According to the sixth aspect, a portion of the liquid in the treatment tank above the upstream end portion of the discharge pipe flows into the discharge pipe. Since the solvent concentration of the upper portion of the liquid is high, the second concentration liquid can be supplied to the organic solvent recovery part through the discharge pipe.

According to the seventh aspect, the first concentration liquid and the second concentration liquid can be separately discharged from the bottom of the treatment tank. In addition, the solvent concentration of the second concentration liquid can be adjusted by adjusting the discharge amount of the first concentration liquid.

According to the eighth aspect, since the flow rate of the liquid flowing out of the bottom of the treatment tank is larger than the flow rate of the liquid flowing into the upstream end portion of the first discharge pipe, the liquid flows into the upstream end portion of the first discharge pipe while staying in the bottom of the chamber. That is, in the first state, the first concentration liquid is discharged through the first discharge pipe while staying in the bottom of the chamber. After the first state, since the tank valve is closed, the first concentration liquid staying at the bottom of the chamber is discharged by the first discharge pipe. Thereafter, the switching valve part selects the second state. Therefore, it is possible to suppress mixing of the second concentration liquid with the first concentration liquid staying at the bottom of the chamber. That is, the discharge part can supply the second concentration liquid to the organic solvent recovery part while suppressing a decrease in the solvent concentration of the second concentration liquid.

According to the ninth aspect, since the rise of the substrate and the discharge of the first concentration liquid are performed in parallel, the throughput of the treatment can be improved.

According to the tenth aspect, the second concentration liquid is taken out from the liquid in the main body tank by causing the second concentration liquid to overflow from the main body tank to the upflow tank, and the discharge part discharges the second concentration liquid from the upflow tank. Therefore, the solvent concentration of the second concentration liquid can be easily adjusted by adjusting the supply amount of pure water.

While the disclosure has been shown and described in detail, the foregoing description is in all aspects illustrative and not restrictive. It is therefore understood that numerous modifications and variations can be devised.

What is claimed is:

1. A substrate processing apparatus comprising:
a treatment tank for storing liquid;
a substrate holder that holds a plurality of substrates and immerses said plurality of substrates in said liquid in said treatment tank;
a discharge part that discharges a second concentration liquid having a solvent concentration higher than a solvent concentration of a first concentration liquid from said treatment tank in which said liquid containing water and an organic solvent having a specific gravity smaller than that of said water is stored in a concentration distribution in which a solvent concentration is higher on an upper side than on a lower side, while avoiding at least a part of said first concentration liquid of said liquid; and
an organic solvent recovery part including a dewaterer that separates water from said second concentration liquid discharged by said discharge part to generate a third concentration liquid having a solvent concentration higher than that of said second concentration liquid.

2. The substrate processing apparatus according to claim 1, comprising:
a pure water supply part including a supply pipe through which pure water flows toward said treatment tank;
a solvent vapor supply part including an ejection pipe that ejects vapor of said organic solvent having higher volatility than said pure water into a space above said treatment tank; and
a controller, wherein
said substrate holder moves up and down said plurality of substrates between an immersion position inside said treatment tank and a position above said treatment tank, and
said controller
causes said pure water supply part to supply said pure water to said treatment tank, and causes said substrate holder to lower said plurality of substrates to said immersion position to immerse said plurality of substrates in said pure water;
causes said solvent vapor supply part to eject said vapor from said ejection pipe in an immersion state in which said plurality of substrates are immersed in said pure water to form a liquid membrane of said organic solvent on a liquid surface of said treatment tank;
raises said plurality of substrates from said immersion position in a state where said liquid membrane is formed; and
causes said discharge part to discharge said second concentration liquid from said treatment tank in a non-immersion state in which said plurality of substrates are located above said treatment tank.

3. The substrate processing apparatus according to claim 2, further comprising
a pressure regulator that adjusts a pressure in a treatment chamber in which said treatment tank is accommodated, wherein
said controller
dries said plurality of substrates in a state where the pressure in said treatment chamber is reduced to a first pressure value by said pressure regulator; and
causes said discharge part to discharge said second concentration liquid from said treatment tank in a state where said pressure regulator adjusts the pressure in said treatment chamber to be higher than said first pressure value.

4. The substrate processing apparatus according to claim 1, wherein a solvent concentration of said second concentration liquid is equal to or more than a lower limit value of an application range of a solvent concentration of said dewaterer.

5. The substrate processing apparatus according to claim 4, wherein said dewaterer includes a membrane separator having a separation membrane through which water contained in said second concentration liquid passes.

6. The substrate processing apparatus according to claim 1, wherein
said discharge part includes:
a discharge pipe having an upstream end portion to be immersed in said liquid in said treatment tank at a height position corresponding to said second concentration liquid and a downstream end portion connected to said organic solvent recovery part; and
a discharge valve interposed in said discharge pipe.

7. The substrate processing apparatus according to claim 1, wherein
said discharge part includes:
a first discharge pipe that communicates with a bottom of said treatment tank;
a second discharge pipe that communicates with said bottom of said treatment tank and is connected to said organic solvent recovery part;
a switching valve part that switches between a first state in which said liquid from said bottom of said treatment tank flows through said first discharge pipe and a second state in which said liquid flows through said second discharge pipe; and
a controller that causes said switching valve part to select said first state to discharge said first concentration liquid from said bottom of said treatment tank, and then causes said switching valve part to select said second state to discharge said second concentration liquid from said bottom of said treatment tank.

8. The substrate processing apparatus according to claim 7, comprising
a chamber accommodating said treatment tank, wherein
said discharge part further includes a tank valve that switches opening and closing of said bottom of said treatment tank,
an upstream end portion of said first discharge pipe is connected to a bottom of said chamber,
a flow rate of said liquid flowing out of said bottom of said treatment tank is larger than a flow rate of said liquid flowing into said upstream end portion of said first discharge pipe, and
said controller causes said switching valve part to select said second state from said first state via an interrupted state in which said tank valve is closed.

9. The substrate processing apparatus according to claim 7, comprising:
a pure water supply part that includes a supply pipe, pure water flowing toward said treatment tank through said supply pipe to be stored in said treatment tank; and
a solvent vapor supply part including an ejection pipe that ejects vapor of said organic solvent having higher volatility than said pure water into a space above said treatment tank, wherein
said substrate holder moves up and down said plurality of substrates between an immersion position inside said treatment tank and a position above said treatment tank, and
said controller
causes said pure water supply part to supply said pure water to said treatment tank, and causes said substrate holder to lower said plurality of substrates to said immersion position to immerse said plurality of substrates in said pure water,
causes said ejection pipe to eject said vapor of said organic solvent in an immersion state in which said plurality of substrates are immersed in said pure water in said treatment tank to form a liquid membrane of said organic solvent on a liquid surface in said treatment tank, and
causes said switching valve part to select said first state to cause said liquid in said treatment tank to flow to said first discharge pipe as said first concentration liquid while causing said substrate holder to raise said plurality of substrates in a state where said liquid membrane is formed.

10. The substrate processing apparatus according to claim 1, comprising
a controller, wherein
said treatment tank includes:
a main body tank that stores said liquid; and
an upflow tank that receives said liquid overflowing from an upper portion of said main body tank,
said discharge part includes:
an upflow pipe that is provided in a lower portion of said treatment tank, and ejects pure water into said treatment tank to overflow said liquid from said main body tank; and
a discharge pipe including an upstream end portion connected to said upflow tank and a downstream end portion connected to said organic solvent recovery part, and
said controller causes said discharge part to eject said pure water from said upflow pipe to cause said second concentration liquid in said liquid in said treatment tank to flow into said upflow tank and cause said second concentration liquid to be supplied from said upflow tank to said organic solvent recovery part through said discharge pipe.
